(19) United States
(12) Patent Application Publication
(10) Pub. No.: US 2023/0369277 A1
(43) Pub. Date: Nov. 16, 2023

(54) LIQUID PHASE BONDING FOR ELECTRICAL INTERCONNECTS IN SEMICONDUCTOR PACKAGES

(71) Applicant: SEMICONDUCTOR COMPONENTS INDUSTRIES, LLC, Scottsdale, AZ (US)

(72) Inventors: Michael J. SEDDON, Gilbert, AZ (US); Chee Hiong CHEW, Seremban (MY)

(73) Assignee: SEMICONDUCTOR COMPONENTS INDUSTRIES, LLC, Scottsdale, AZ (US)

(21) Appl. No.: 18/357,644

(22) Filed: Jul. 24, 2023

Related U.S. Application Data
(63) Continuation-in-part of application No. 17/304,715, filed on Jun. 24, 2021.
Application No. 17/304,715 is a continuation of application No. 15/410,288, filed on Jan. 19, 2017, now Pat. No. 11,049,833.
Application No. 15/410,288 is a division of application No. 14/606,667, filed on Jan. 27, 2015, now Pat. No. 9,564,409.

(51) Int. Cl. H01L 23/00; H01L 21/78; H01L 23/482; H01L 21/683

(52) U.S. Cl. CPC H01L 24/32; H01L 24/11; H01L 21/78; H01L 23/482; H01L 24/05; H01L 24/13; H01L 24/16; H01L 24/27; H01L 24/29; H01L 21/6836; H01L 24/83; H01L 24/94; H01L 24/28; H01L 24/30; H01L 24/31; H01L 24/33; H01L 2224/13166; H01L 2224/13155; H01L 2224/13147; H01L 2224/13139; H01L 2224/13111; H01L 2924/01327; H01L 2224/11849; H01L 2224/1308; H01L 2224/8481; H01L 2224/8581; H01L 2224/8681; H01L 21/4825

(57) ABSTRACT

Implementations of a semiconductor package may include a pin coupled to a substrate. The pin may include a titanium sublayer, a nickel sublayer, and one of a silver and tin intermetallic layer or a copper and tin intermetallic layer, the one of the silver and tin intermetallic layer or the copper and tin intermetallic layer having a melting temperature greater than 260 degrees Celsius. The one of the silver and tin intermetallic layer or the copper and tin intermetallic layer may be formed by reflowing a tin layer and one of a silver layer or copper layer with a silver layer of the substrate where the substrate may be directly coupled to the one of the silver and tin intermetallic layer or the copper and tin intermetallic layer. The substrate may include a copper layer that was directly coupled with the silver layer before the reflow.

### CROSS REFERENCE TO RELATED APPLICATIONS

This application is a continuation-in-part application to the earlier U.S. Utility patent application to Seddon entitled, “Semiconductor Packages with an Intermetallic Layer,” application Ser. No. 17/304,715, filed Jun. 24, 2021, now pending; which application is a continuation application of the earlier U.S. Utility Patent Application to Seddon entitled “Semiconductor Packages with an Intermetallic Layer,” application Ser. No. 15/410,288, filed Jan. 19, 2017, now U.S. patent Ser. No. 11/049,833, issued Jun. 29, 2021; which application is a divisional application of the earlier U.S. Utility Patent Application to Seddon entitled “Methods of Forming Semiconductor Packages with an Intermetallic Layer comprising Tin and at least one of Silver, Copper or Nickel,” application Ser. No. 14/606,667, filed Jan. 27, 2015, now issued as U.S. Pat. No. 9,564,409, the disclosures of each of which are hereby incorporated entirely herein by reference.

### BACKGROUND

### 1. Technical Field

Aspects of this document relate generally to electronic interconnect structures, such as pin structures for semiconductor packages.

### 2. Background

Semiconductor packages have been devised to allow for the protection of semiconductor die from contaminants, humidity, mechanical stress, or electrostatic discharge. Various semiconductor package types also allow for routing of electrical signals to and from the semiconductor die.

### SUMMARY

Implementations of a semiconductor package may include a pin coupled to a substrate. The pin may include a titanium sublayer, a nickel sublayer, and one of a silver and tin intermetallic layer or a copper and tin intermetallic layer, the one of the silver and tin intermetallic layer or the copper and tin intermetallic layer having a melting temperature greater than 260 degrees Celsius. The one of the silver and tin intermetallic layer or the copper and tin intermetallic layer may be formed by reflowing a tin layer and one of a silver layer or copper layer with a silver layer of the substrate and the substrate may be directly coupled to the one of the silver and tin intermetallic layer or the copper and tin intermetallic layer. The substrate may include a copper layer that was directly coupled with the silver layer before the one of the silver and tin intermetallic layer or the copper and tin intermetallic layer was reflowed.

Implementations of a semiconductor package may include one, all, or any of the following:

The package may include where an intervening layer was coupled between the nickel sublayer and a copper layer in the copper and tin intermetallic layer before the copper and tin intermetallic layer was reflowed.

The nickel sublayer may be between the titanium sublayer and one of the silver and tin intermetallic layer or the copper and tin intermetallic layer.

The passivation layer of a die coupled to the substrate may include one of an oxide, nitride, or polyimide.

The pin may include an upper contact portion including a contact surface configured to mechanically and electrically couple with a pin receiver; a lower portion including a single vertical stop and at least two curved legs; a horizontal base coupled directly to the at least two curved legs; and a gap between a bottom contact surface of the single vertical stop and an upper contact surface of the horizontal base. The single vertical stop may be located between the at least two curved legs.

The pin may include an upper contact portion including a contact surface configured to mechanically and electrically couple with a pin receiver; a lower portion bent into a single N-shape including a first section and a second section; a horizontal base coupled directly to the second section of the lower portion and having an upper contact surface and the horizontal base extending substantially perpendicularly beyond a width of the upper contact portion; and a gap between a lower contact surface of the first section and the horizontal base.

The pin may include an upper contact portion including a contact surface configured to mechanically and electrically couple with a pin receiver; a lower portion including a single vertical stop and at least two curved legs. The at least two curved legs may include a first portion and a second portion and a horizontal base coupled directly to the second portion of the at least two curved legs and having an upper contact surface. The horizontal base may extend substantially perpendicularly beyond a width of the upper contact portion. A gap may be present between a bottom contact surface of the single vertical stop and the upper contact surface of the horizontal base. The single vertical stop may be located between the at least two curved legs.

The pin may include an upper portion and a lower portion including a single vertical stop. The lower portion may include at least two curved portions, each curved portion including one of an s-shape or a c-shape. A horizontal base may be coupled directly to the at least two curved portions; and a gap may be present between the single vertical stop and an upper contact surface of the horizontal base where each of the at least two curved portions further include a tapered portion coupled directly with the horizontal base.

Implementations of a semiconductor package may include a pin including a metal layer on an end of the pin; and a substrate including an opening therein, the opening including a metal layer. The metal layer of the end of the pin may be configured to reflow with the metal layer included in the opening in the substrate after the end of the pin may be inserted into the opening.

Implementations of a semiconductor package may include one, all, or any of the following:

The metal layer on the end of the pin may include a titanium sublayer, a nickel sublayer, and one of a silver and tin intermetallic layer or a copper and tin intermetallic layer where the one of the silver and tin intermetallic layer or the copper and tin intermetallic layer may have a melting temperature greater than 260 degrees Celsius. The one of the silver and tin intermetallic layer or the copper and tin intermetallic layer may be formed by reflowing a tin layer and one of a silver layer or copper layer with a silver layer included in the metal layer of the substrate.

The substrate may be directly coupled to the one of the silver and tin intermetallic layer or the copper and tin intermetallic layer where the substrate may include a copper layer that was directly coupled with the silver layer before the one of the silver and tin intermetallic layer or the copper and tin intermetallic layer was reflowed.

An intervening layer may be coupled between the nickel sublayer and a copper layer in the copper and tin intermetallic layer before the copper and tin intermetallic layer was reflowed.

The nickel sublayer may be between the titanium sublayer and one of the silver and tin intermetallic layer or the copper and tin intermetallic layer.

The end of the pin may be a rod with a substantially perpendicular edge.

The end of the pin may be a rod with one of a beveled edge, a chamfered edge, or an angled edge.

Implementations of a semiconductor package may include a pin including a base, the base including one or more projections extending therefrom and a metal layer on the base; and a substrate including an opening therein including one or more recesses configured to receive the one or more projections of the pin. The opening may include a metal layer. The metal layer of the base may be configured to reflow with the metal layer included in the opening in the substrate after the one or more projections of the pin may be inserted into the one or more recesses of the opening.

Implementations of a semiconductor package may include one, all, or any of the following:

The one or more projections may be one of a right triangular pyramid, a rectangular solid, a pyramid, a conical frustum, or a cone.

The one or more projections may be distributed along a largest planar surface of the base.

The one or more projections may be located at edges of a largest planar surface of the base.

The base may include a curved surface from which the one or more projections extend therefrom.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross section view of a die, multiple metallic layers, and a substrate used in the formation of an implementation of a semiconductor device package;

FIG. 2 is a cross section view of an implementation of a semiconductor device package formed from the elements of FIG. 1;

FIG. 3 is a cross section view of a die, multiple metallic layers, and a substrate used in the formation of an implementation of a semiconductor device package;

FIG. 4 is a cross section view of an implementation of a semiconductor device package formed from the elements of FIG. 3

FIG. 5 is a cross section view of a die, multiple metallic layers, and a substrate used in the formation of an implementation of a semiconductor device package;

FIG. 6 is a cross section view of an implementation of a semiconductor device package formed from the elements of FIG. 5;

FIG. 7 is a cross section view of a die, multiple metallic layers, and a substrate used in the formation of an implementation of a semiconductor device package;

FIG. 8 is a cross section view of an implementation of a semiconductor device package formed from the elements of FIG. 7;

FIG. 9 is a cross section view of a die, multiple metallic layers, and a substrate used in the formation of an implementation of a semiconductor device package;

FIG. 10 is a cross section view of an implementation of a semiconductor device package formed from the elements of FIG. 9;

FIG. 11 is a cross section view of a die, multiple metallic layers, and a substrate used in the formation of an implementation of a semiconductor device package;

FIG. 12 is a cross section view of an implementation of a semiconductor device package formed from the elements of FIG. 11;

FIG. 13 is a copper-tin binary phase diagram;

FIG. 14 is a silver-tin binary phase diagram;

FIG. 15 illustrates an example of a processing step that can be performed in the formation of the semiconductor device package of any of FIGS. 2, 4, 6, 8 and 10;

FIG. 16 illustrates an example of another processing step that can be performed in the formation of the semiconductor device package of any of FIGS. 2, 4, 6, 8 and 10;

FIG. 17 illustrates an example of another processing step that can be performed in the formation of the semiconductor device package of any of FIGS. 2, 4, 6, 8 and 10;

FIG. 18 illustrates an example of another processing step that can be performed in the formation of the semiconductor device package of any of FIGS. 2, 4, 6, 8 and 10;

FIG. 19 is a cross section view of a die with die pads on a top side of the die exposed through a passivation layer;

FIG. 20 illustrates an example of a processing step that can be performed in the formation of the semiconductor device package of FIG. 12;

FIG. 21 illustrates an example of another processing step that can be performed in the formation of the semiconductor device package of FIG. 12;

FIG. 22 illustrates an example of another processing step that can be performed in the formation of the semiconductor device package of FIG. 12;

FIG. 23 illustrates an example of another processing step that can be performed in the formation of the semiconductor device package of FIG. 12; and

FIG. 24 is a cross section view of a pin/electrical interconnect with multiple metallic layers coupled thereto and a substrate;

FIG. 25 is a cross section view of the implementation of the pin/electrical interconnect of FIG. 24 following bonding;

FIG. 26 is a cross sectional view of another implementation of a pin/electrical interconnect with multiple metallic layers coupled thereto and a substrate;

FIG. 27 is a cross section of the implementation of the pin/electrical interconnect of FIG. 26 following bonding;

FIG. 28 is a cross sectional view of another implementation of a pin/electrical interconnect with multiple metallic layers coupled thereto and a substrate;

FIG. 29 is a cross sectional view of the pin/electrical interconnect of FIG. 28 following bonding;

FIG. 30 is a cross sectional view of another implementation of a pin/electrical interconnect with multiple metallic layers coupled thereto and a substrate;

FIG. 31 is a cross sectional view of the implementation of the pin/electrical interconnect of FIG. 30 following bonding;

FIG. 32 is a cross sectional view of another implementation of a pin/electrical interconnect with multiple metallic layers coupled thereto and a substrate;

FIG. 33 is a cross sectional view of the pin/electrical interconnect of FIG. 32 following bonding;

FIG. 34 is a cross sectional view of an another implementation of a pin/electrical interconnect and a substrate;

FIG. 35 is a cross sectional view of an another implementation of a pin/electrical interconnect and a substrate when inserted into a hole in the substrate;

FIG. 36 is a cross sectional view of another implementation of a pin/electrical interconnect and a substrate when inserted into a hole in the substrate;

FIG. 37 is a perspective view of an end of a pin/electrical connector above an opening in a substrate configured to receive the end of the pin/electrical connector;

FIG. 38 is a cross sectional view of an end of an implementation of a pin/electrical connector;

FIG. 39 is a cross sectional view of an end of an implementation of a pin/electrical connector;

FIG. 40 is a cross sectional view of an end of an implementation of a pin/electrical connector;

FIG. 41 is a cross sectional view of an end of a pin/electrical connector and a substrate;

FIG. 42 is a perspective view of an implementation of a pin;

FIG. 43 is a perspective view of another implementation of a pin;

FIG. 44 is a perspective view of another implementation of a pin;

FIG. 45 is a perspective view of another implementation of a pin;

FIG. 46 is a perspective view of an implementation of a power module;

FIG. 47 is a side cross sectional view of an implementation of a power module; and

FIG. 48 is a perspective view of another implementation of a pin.

### DESCRIPTION

This disclosure, its aspects and implementations, are not limited to the specific components, assembly procedures or method elements disclosed herein. Many additional components, assembly procedures and/or method elements known in the art consistent with the intended electrical interconnects will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such electrical interconnects, and implementing components and methods, consistent with the intended operation and methods.

As used herein, a die “backside” is defined as a side of the die that either does not have electrical connectors thereon or only has electrical connectors, such as pads or other elements, which are intended to act as an electrical ground or electrical routing to the die. As used herein, a die “top side” is defined as a side of the die that has at least one electrical connector thereon, such as a pad or other element which is not intended solely to act as an electrical ground to the die. As used herein “intermetallic(s)” refers to a solid-state compound having a fixed stoichiometry of two or more elemental metals, the atoms of each elemental metal having fixed rather than random positions within a lattice structure. “Intermetallic layer(s)” as used herein refers more generically to a layer which includes one or more intermetallics but which in some cases may not be entirely formed of intermetallics as defined above.

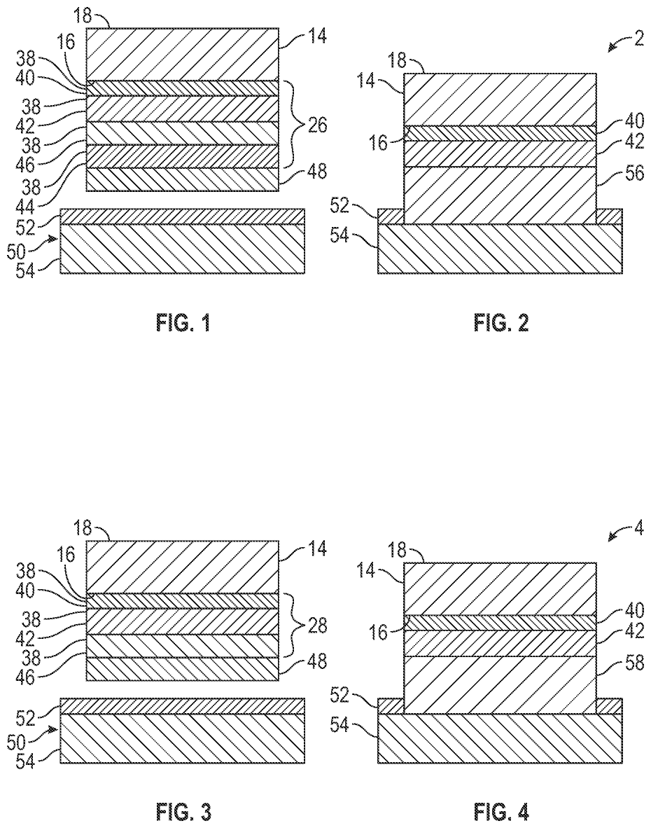

Referring to FIGS. 1-10, various implementations of methods of forming a semiconductor device package (package) involve utilizing wafer backside metallization which is later sawn through or otherwise segmented after the die have been singulated. In FIGS. 1-10 the die have already been singulated and the backside metallization has already been sawn through or otherwise segmented. In implementations the backside metallization, including an intermediate metal layer (including all sublayers), and a tin layer, are all applied using wafer backside metallization techniques prior to the wafer being singulated.

Referring now to FIGS. 1-2, in various implementations of a method of forming a semiconductor device package (package) 2 the method includes forming an intermediate metal layer 26 onto a backside 16 of a die 14. The intermediate metal layer 26 includes a plurality of sublayers 38. A first sublayer 38 including titanium (titanium sublayer) 40 is deposited directly onto the backside 16 of die 14. A sublayer 38 including nickel (nickel sublayer) 42 is deposited directly onto the titanium sublayer 40. As used herein, “deposition directly onto” the titanium sublayer is meant to include any deposition onto an unoxidized/unreduced titanium sublayer as well as deposition onto an oxidized or otherwise reduced film of the titanium sublayer 40 formed prior to the deposition of the nickel sublayer 42 thereon (this same meaning is intended throughout this document whenever one layer is deposited “directly” onto another). A sublayer 38 including copper (copper sublayer) 46 is deposited directly onto the nickel sublayer 42. A sublayer 38 including silver (silver sublayer) 44 is deposited directly onto the copper sublayer 46. In various implementations each sublayer disclosed herein is formed of at least 50 wt. %, at least 80 wt. %, at least 85 wt. %, at least 90 wt. %, at least 95 wt. %, at least 96 wt. %, at least 97 wt. %, at least 98 wt. %, and/or at least 99 wt. % of the metal after which it is named.

The deposition of each sublayer 38, and of all other metal layers described herein, may be done using any thin film chemical and/or physical deposition technique such as, by non-limiting example, plating, electroplating, electroless plating, chemical solution deposition (CSD), chemical bath deposition (CBD), spin coating, chemical vapor deposition (CVD), metalorganic chemical vapor deposition (MOCVD), plasma enhanced CVD (PECVD), atomic layer deposition (ALD), physical vapor deposition (PVD), thermal evaporation, electron beam evaporation, molecular beam epitaxy (MBE), sputtering, pulsed laser deposition, ion beam deposition, cathodic arc deposition (arc-PVD), electrohydrodynamic deposition (electrospray deposition), and any other method of metal layer deposition.

After the aforementioned layers have been deposited using any of the wafer backside metallization techniques as described above, the wafer may be singulated to produce single units as shown in FIG. 1 which may then be attached to a substrate 50. In some implementations, the layers may be deposited after singulation into single units, however. In implementations the substrate 50 is a portion of a ceramic board. Some representative examples of singulation processes will be described hereafter. The substrate 50 includes a silver layer 52 atop a copper layer 54 and the bottom tin layer 48 is reflowed with the silver layer 52 using a 260 degrees Celsius reflow profile, such that the silver sublayer 44 and copper sublayer 46 also melt or at least become softened or diffuse/intermix sufficiently for the silver of the silver sublayer 44 and copper of the copper sublayer 46 to mix with the tin of the tin layer 48 to form intermetallics of tin, silver and/or copper. The tin layer 48 is pure tin or substantially pure tin and melts at 231 degrees Celsius and wets well to the substrate 50 with minimum voiding. The presence of silver and copper, even in small amounts, with the molten tin, results in the formation of intermetallics of one or more of silver, tin and/or copper fairly quickly, the intermetallics having melting temperatures (i.e., liquidus temperatures) greater than that of tin, which prevents or helps to prevent the flow of tin across the substrate 50 laterally.

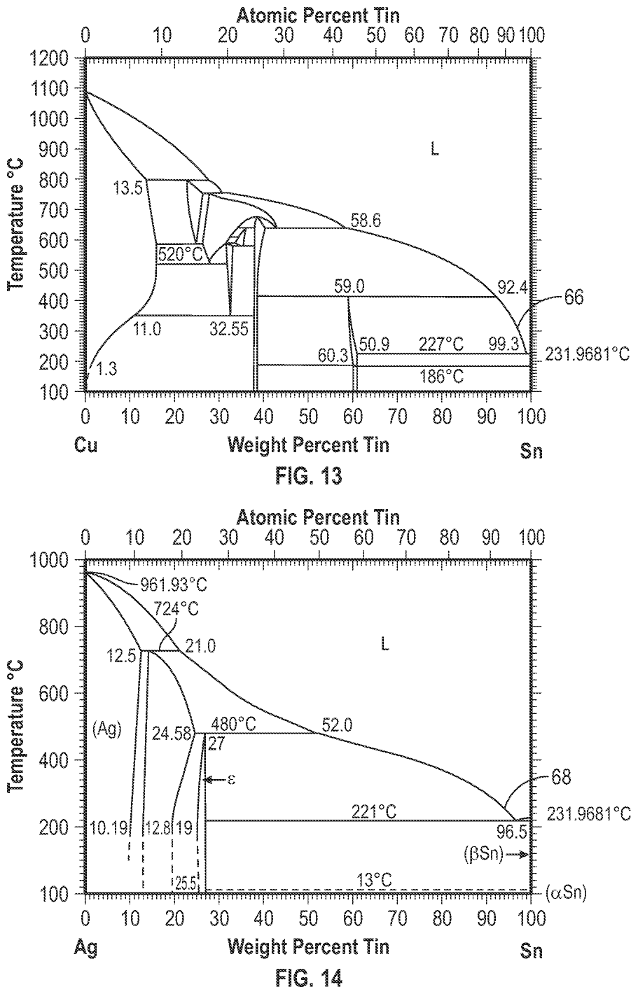

Referring to the binary phase diagram of the copper/tin system of FIG. 13, even a small weight percent of about 2-3% copper in tin, at point 66 on the phase diagram, will raise the liquidus temperature from about 232 degrees Celsius to about 260 degrees Celsius. The liquidus temperature is the line above which only liquid phase(s) exist—the solidus temperature is the line below which only solid phase(s) exist. Between the liquidus and solidus temperatures some solid and some liquid phases may exist. For purposes of this disclosure, the liquidus temperature corresponds with the melting point, or melting temperature of a material. Referring to the binary phase diagram of the silver/tin system of FIG. 14, even a small weight percent of about 6% silver in tin, at point 68 on the phase diagram, will raise the liquidus temperature from about 232 degrees Celsius to about 260 degrees Celsius—while the solidus temperature remains at 221 degrees Celsius. At 10 wt. % of silver and 90 wt. % tin the liquidus temperature is 295 degrees Celsius while the solidus temperature remains at 221 degrees Celsius. At 5 wt. % silver and 95 wt. % tin the liquidus temperature is 240 degrees Celsius and the solidus temperature is 221 degrees Celsius. At about 27 wt. % silver and about 73 wt. % tin the liquidus temperature is 400 degrees Celsius and the solidus temperature remains 221 degrees Celsius. In various implementations, a 3 micron solder joint could be formed during reflow to form a 73 wt. % tin 27 wt. % silver structure by beginning with a 1.793 micron layer of tin and a 1.207 micron layer of silver prior to reflow.

The raising of the melting temperature of the intermetallic layer 56 of the semiconductor package 2 thus results in a structure which will not reflow and/or re-melt during subsequent temperature increases when other devices are being reflowed or otherwise attached to the substrate 50 using a standard 260 degrees Celsius reflow profile. The properties of the intermetallic layer 56 thus produce a “single reflow” package or, in other words, the intermetallic layer 56 is a “single reflow” layer that will only reflow once under a standard 260 degrees Celsius reflow profile. This allows the die 14 to stay in place during subsequent reflows when other devices are mounted to the board of which the substrate 50 is a part. Backmetal layers of titanium/nickel/gold-tin described more below, and other backmetal materials, do not have an increased melting temperature after the first reflow, but are susceptible to reflowing again when experiencing the same reflow profile temperature.

In terms of actual localized composition, there may be many different intermetallics or intermetallic compounds within the intermetallic layer 56 which may include any intermetallics comprising two or more of silver, tin and/or copper, though the intermetallic layer 56 may also be partially in the form of a solution. In other words, there may be some pure tin, some pure copper, some pure silver, some pure nickel, and so forth, in solution, with some intermetallics interspersed throughout, such as precipitated intermetallic crystals in solid solution, and/or there may be planar intermetallic layers particularly at boundary points (such as the boundary of the intermetallic layer 56 with the copper layer 54 and with the copper sublayer 46 (or the bottommost sublayer 38 after reflow in the other examples described herein), without the entire intermetallic layer 56 being comprised of intermetallics of two or more of silver, tin and/or copper. Nevertheless the intermetallic layer 56 due to the presence of the intermetallics in the layer 56 ultimately has a melting temperature greater than 260 degrees Celsius so that it does not reflow during subsequent high temperature processes that will include raising the temperature of the substrate 50 and/or the semiconductor package 2 to, or to about, 260 degrees Celsius.

The final composition of intermetallics in the intermetallic layer 56 may vary between a wide range since, as shown with the phase diagrams, only just above 2 weight percent copper or 4 weight percent silver needs to be mixed in with the tin to raise the melting temperature of the overall mixture above 260 degrees Celsius and, when more silver or copper are added, the melting temperature continues to increase. With a titanium/nickel/gold-tin back metallization described further below there is a fairly limited window of thermal operation as the gold-tin layer (which in some implementations is 3 microns thick) requires a composition that is 80+/−0.8 wt. % gold.

The layers of the structure of FIG. 1 may have the following thicknesses. The titanium sublayer 40 may be, or may be about, 1.15 kiloAngstroms (kÅ) thick, though a wide range of thicknesses could be used. This sublayer is used for adhesion to the silicon of the die 14 and can be replaced with other materials such as titanium-tungsten (TiW), chromium (Cr), nickel-chromium (NiCr), and the like. The nickel sublayer 42 may be, or may be about, 1 kÅ to about 6 kÅ. In particular implementations it may be 5 kÅ. This layer may be thicker for higher temperature applications (such as for high temperature storage requirements for hotter light emitting diodes (LEDs)), or when the tin layer 48 is thicker so that there is less of a risk of much or most (or all) of the nickel being consumed into nickel-tin intermetallics which is generally undesirable, and/or when the substrate 50 does not include a silver layer 52 to consume some of the tin into silver-tin intermetallics thereby reducing the formation of nickel-tin intermetallics. Too thick of a nickel sublayer 42 may result in excessive stresses. The copper sublayer 46 may be, or may be about, 4 kÅ thick, and in implementations may range from 0.1 kÅ to 12 kÅ. The silver sublayer 44 may be, or may be about, 2 kÅ thick, and in implementations may range between 0.5 kÅ and 12 kÅ or between 0 kÅ and 12 kÅ (in some implementations, as described herein, there is no silver sublayer 44 at all). In implementations the tin layer 48 may be, or may be about, 16 kÅ thick, and in implementations may range from 10 kÅ to 30 kÅ.

The ratio of silver to tin can be adjusted based on the application. Increasing the thickness of the tin layer 48 allows for additional or enhanced wetting to substrate 50 and reduction of voids if the surface of the substrate 50 is rough. Increasing the thickness of the silver sublayer 44 increases protection of the nickel (i.e., preventing the nickel from being consumed into nickel-tin intermetallics). It can, however, be desirable that some of the nickel, but not all of the nickel, be consumed in nickel-tin intermetallics. Accordingly, if the silver sublayer 44 is too thick this can restrict the amount of nickel-tin intermetallics too much and can actually reduce the shear strength and consistency of the semiconductor package 2. The ratio of silver to tin may thus be adjusted so that the desired silver-tin intermetallics in the desired amount are formed during reflow. The ratio of copper to tin can also be adjusted based on the particular application. Increasing the thickness of the copper sublayer 46 allows for a thicker tin layer 48 because a thicker copper sublayer 46 better slows down or impedes the formation of nickel-tin intermetallics.

As can be seen from comparing FIG. 2 to FIG. 1, the tin layer 48, silver layer 52 of the substrate 50, silver sublayer 44, and copper sublayer 46 may be consumed in the intermetallic layer 56. The use of the sublayers 38 and tin layer 48 may also allow for adhesion of the die 14 to the substrate 50 without the use of solder paste or preforms. The copper layer 54 and the portion of the copper sublayer 46 that remains may provide solderable surfaces for the tin and intermetallics and other elements of the intermetallic layer 56. In implementations the copper of the copper layer 54 of the substrate 50 may also form intermetallics with the tin of the tin layer 48, further providing a strong die attach and reducing the amount of nickel-tin intermetallics by consuming some of the tin into tin-copper intermetallics.

FIGS. 3-4 show a similar materials system to that shown in FIGS. 1-2 but with an intermediate metal layer 28 that does not include a silver sublayer 44. The remaining layers may have the same thicknesses described above. The processes and results are similar to above, except that the intermetallic layer 58 may include somewhat different overall percentages of silver, copper and tin and therefore may have different intermetallics and/or different amounts of different intermetallics, different amounts of metals or compounds precipitated or in solution, etc. Nevertheless intermetallic layer 58 has a melting temperature greater than 260 degrees Celsius and semiconductor package 4 otherwise generally has similar single-reflow properties as those described above with respect to semiconductor package 2. As can be seen by comparing FIG. 3 to FIG. 4 the copper sublayer 46, tin layer 48 and silver layer 52 of the substrate 50 may be fully or partially consumed in the intermetallic layer 58.

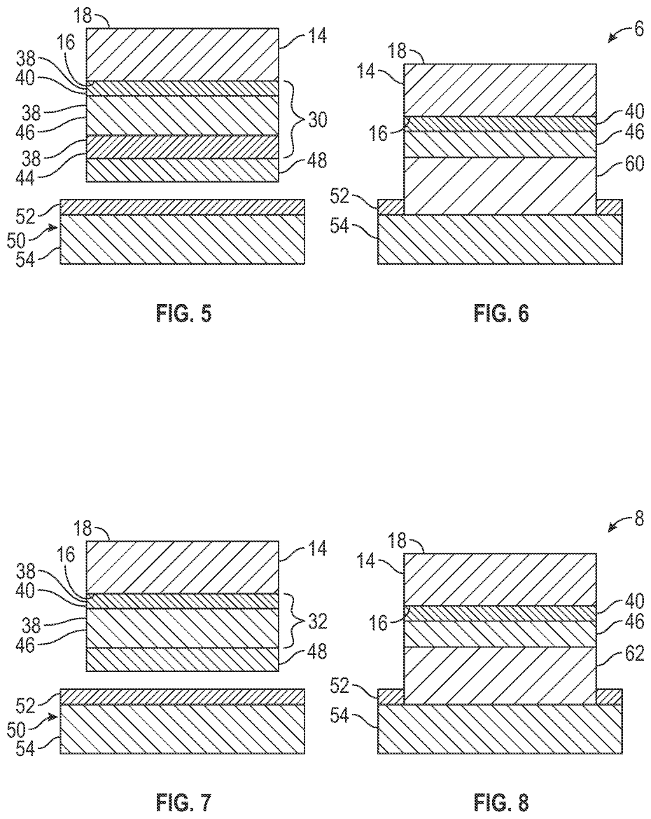

FIGS. 5-6 show a similar materials system to that shown in FIGS. 1-2 but with an intermediate metal layer 30 that does not include a nickel sublayer 42. The remaining layers may have the thicknesses described above, though in implementations the thickness of the copper sublayer 46 may range between 1 kÅ and 40 kÅ. The processes and results are similar to above, however, except that the intermetallic layer 60 may have somewhat different overall percentages of silver, copper and tin and therefore may have different intermetallics and/or different amounts of different intermetallics, different amounts of metals or compounds precipitated or in solution, etc. Nevertheless intermetallic layer 60 has a melting temperature greater than 260 degrees Celsius and semiconductor package 6 otherwise generally has similar single-reflow properties as those described above with respect to semiconductor package 2. As can be seen by comparing FIG. 5 to FIG. 6 the tin layer 48, silver sublayer 44, a portion of the copper sublayer 46, and the silver layer 52 of the substrate 50 may be consumed in the intermetallic layer 60.

FIGS. 7-8 show a similar materials system to that shown in FIGS. 1-2 but with an intermediate metal layer 32 that does not include a nickel sublayer 42 or a silver sublayer 44. The remaining layers may have the thicknesses described above. The processes and results are similar to above, however, except that the intermetallic layer 62 may include somewhat different overall percentages of silver, copper and tin and therefore may have different intermetallics and/or different amounts of different intermetallics, different amounts of metals or compounds precipitated or in solution, etc. Nevertheless intermetallic layer 62 has a melting temperature greater than 260 degrees Celsius and semiconductor package 8 otherwise generally has similar single-reflow properties as those described above with respect to semiconductor package 2. As can be seen by comparing FIG. 7 to FIG. 8 the tin layer 48, a portion of the copper sublayer 46, and the silver layer 52 of the substrate 50 are fully or partially consumed in the intermetallic layer 62.

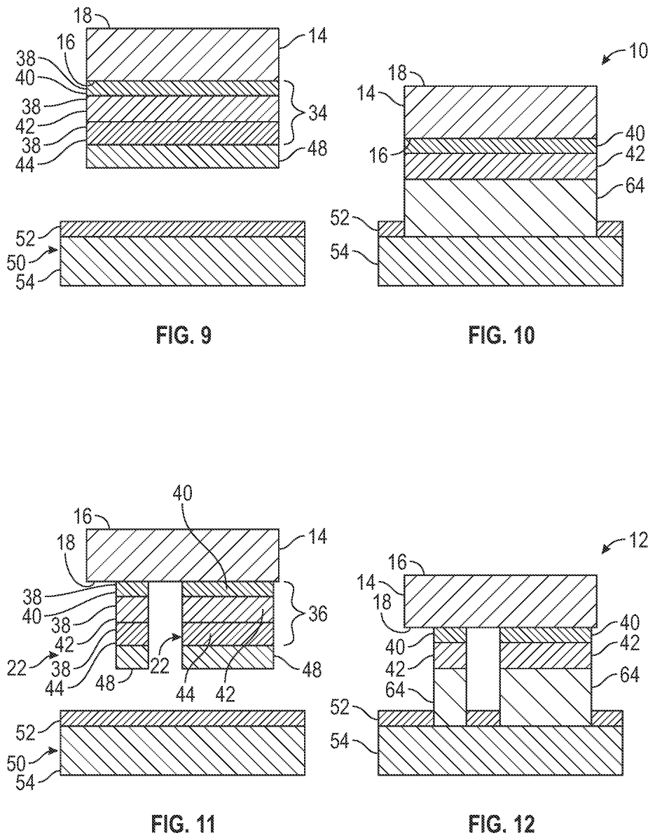

FIGS. 9-10 show a similar materials system to that shown in FIGS. 1-2 but with an intermediate metal layer 34 that does not include a copper sublayer 46. The remaining layers may have the thicknesses described above, though in implementations the silver sublayer 44 may have a thickness of 4 kÅ and may range between 1 kÅ and 12 kÅ. The processes and results are similar to above, however, except that the intermetallic layer 64 may have somewhat different overall percentages of silver, copper and tin and therefore may have different intermetallics and/or different amounts of different intermetallics, different amounts of metals or compounds precipitated or in solution, etc. In particular, since there is no copper sublayer 46, and although there may be some copper in the intermetallic layer 64 from the copper layer 54 of the substrate 50, the intermetallics of the intermetallic layer 64 may predominantly comprise intermetallics of silver and tin. Intermetallics of copper and tin may form at the interfaces of the intermetallic layer 64 and the copper layer 54 of the substrate 50, though. Intermetallic layer 64 also has a melting temperature greater than 260 degrees Celsius and semiconductor package 10 otherwise generally has similar single-reflow properties as those described above with respect to semiconductor package 2. As can be seen by comparing FIG. 9 to FIG. 10 the tin layer 48, silver sublayer 44, and the silver layer 52 of the substrate 50 may be consumed in the intermetallic layer 64 during reflow. The silver sublayer 44 between the nickel sublayer 42 and the tin layer 48 impedes the diffusion of the tin with the nickel and limits the formation of nickel-tin intermetallics, which may allow for a stronger die bond or solder joint.

The materials systems of FIGS. 9 and 11 could in some implementations experience problems with all or substantially all of the nickel being consumed into nickel-tin intermetallics if too thick a tin layer 48 is included. By non-limiting example, in implementations a thicker tin layer 48 may be required for reflowing onto rougher substrates 50 (such as rougher ceramic substrates), when the substrate 50 is not a part of a ceramic substrate, when less voiding is required, or when a taller solder joint is needed for increased reliability. In such instances the ratio of tin to silver is increased, and in such instances the implementations of FIG. 1, 3, 5 or 7 may be used instead which either do not include a nickel sublayer 42 or include a copper sublayer 46 between the tin layer 48 and the nickel sublayer 42 in order to prevent or hinder the formation of nickel-tin intermetallics (by consuming some of the tin into tin-copper intermetallics). The reduction of nickel-tin intermetallics may result in a stronger die bond/solder joint. Some nickel-tin intermetallics can be desirable and show good wetting and adhesion during reflow but when all of the nickel is consumed by the tin into nickel-tin intermetallics so that there is no longer any pure nickel remaining then the adhesion is generally decreased and the shear strength of the semiconductor package reduced.

Furthermore, the nickel sublayer 42 is a high stress metallization which can be more difficult to separate during singulation than other backmetals. For example, depending on the die size, the nickel sublayer 42 could be difficult to separate using a jet ablation process if the nickel sublayer 42 is thicker than 1 micron. In particular implementations, it may also be desirable to form a semiconductor package without nickel for different die shapes or for extremely small die 14, such as less than 180 microns on a side, or very thin die 14, such as less than 100 microns thick. Such die can have inherently high stresses which means that nickel is not a viable (or not as viable an) option. In addition, because the jet ablation force required to break a thick nickel layer may place force on the die greater than the attractive force between the die and the tape, attempting to jet ablate thick nickel may result in washing the die off the tape. In such implementations, the nickel sublayer 42 may be replaced with a copper sublayer 46. Such a replacement may also improve performance during the jet ablation process.

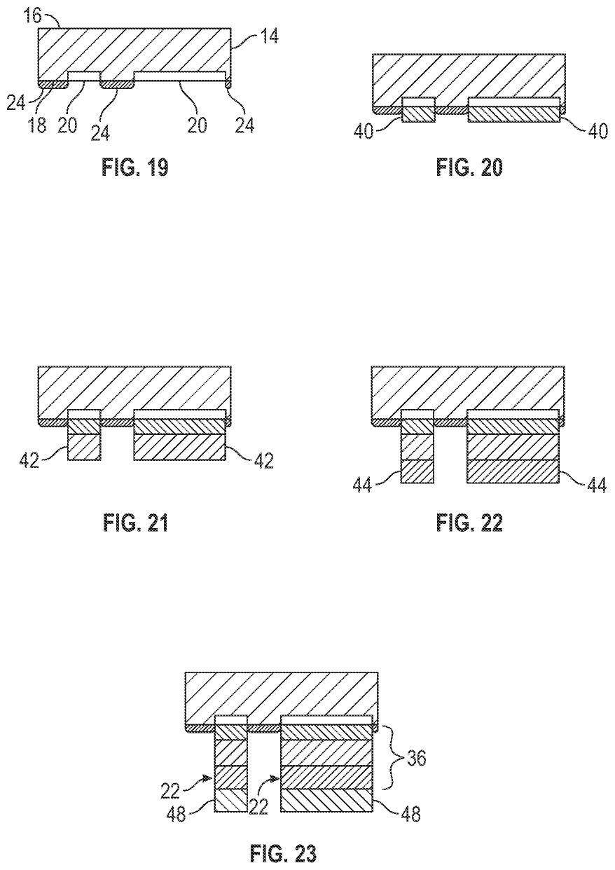

FIGS. 11-12 show a semiconductor package 12 formed using a different method implementation wherein an intermediate metal layer 36 is applied to the top side 18 of die 14, instead of the backside 16, in order to form bumps 22, for flip chip packaging. The layers in such method implementations may still have any of the thicknesses described above. Similar to what was described above with respect to the backmetal method implementations, the flip chip process may also be done to an entire wafer prior to singulation and reference is now made to FIGS. 19-23 and to FIGS. 11-12 to describe this process. The top side 18 of each die 14 prior to singulation includes a plurality of pads 20 (which are electrical contacts not intended to be used primarily as a ground) where each pad 20 is surrounded by a passivation layer 24, as shown in FIG. 19. The passivation layer may be, by non-limiting example, an oxide, nitride, a polyimide, or other material capable of passivating a silicon surface, and may be formed using any of a wide variety of passivating process methods for depositing/forming such materials.

Each sublayer 40 of the intermediate metal layer 36 is deposited in turn, beginning with the sublayer 40 deposited directly onto the pads 20 as shown in FIG. 20. The passivation layer 24 (or a masking material over the passivating layer 24 that is later removed) prevents electrical connection from forming during deposition (via electroplating, sputtering, evaporating, etc.) of sublayers 40 onto the spaces between the pads 20. Thus, as the sublayers 40 are deposited and as the tin layer 48 is deposited, the bumps 22 are formed. FIGS. 20-22 show, as a representative example, a titanium sublayer 40 deposited directly onto each pad 20 (FIG. 20), a nickel sublayer 42 deposited directly onto each titanium sublayer 40 (FIG. 21), and a silver sublayer 44 deposited directly onto each nickel sublayer 42 (FIG. 22). A tin layer 48 is deposited directly onto each silver sublayer 44 (FIG. 23). The tin layers 48 are then reflowed with the silver layer 52 of the substrate 50 which also causes the silver sublayers 44 to melt or at least soften and become diffuse, thus forming intermetallic layers 64, each of which may consume a silver sublayer 44, a tin layer 48 and the silver layer 52 of the substrate 50 directly below the bump 22. The selective deposition of each metallic layer only onto the portions without passivation may be done, by non-limiting example, using electroplating, electroless plating and other methods of metal layer deposition.

Although the intermediate metal layer 36 illustrated in the figures is similar to intermediate metal layer 34 of FIG. 9, this is only given as a representative example and the flip-chip procedure of FIGS. 11-12 could instead have the intermediate metal layers 32 as arranged in FIG. 7, or the intermediate metal layers 30 as arranged in FIG. 5, the intermediate metal layers 28 as arranged in FIG. 3, or the intermediate metal layers 26 as arranged in FIG. 1. In any case, the processes and results are similar to above as described with respect to the backmetal structures shown in FIGS. 1-10, with the resulting intermetallic layer having different overall percentages of silver, copper and tin and therefore having different intermetallics and/or different amounts of different intermetallics, different amounts of metals or compounds precipitated or in solution, etc. according to the particular sublayers 38 used. Whatever sublayers 38 are used, the intermetallic layer 64 of semiconductor package 12 has a melting temperature greater than 260 degrees Celsius and thus the semiconductor package 12 has similar single-reflow properties as those described above with respect to semiconductor package 2.

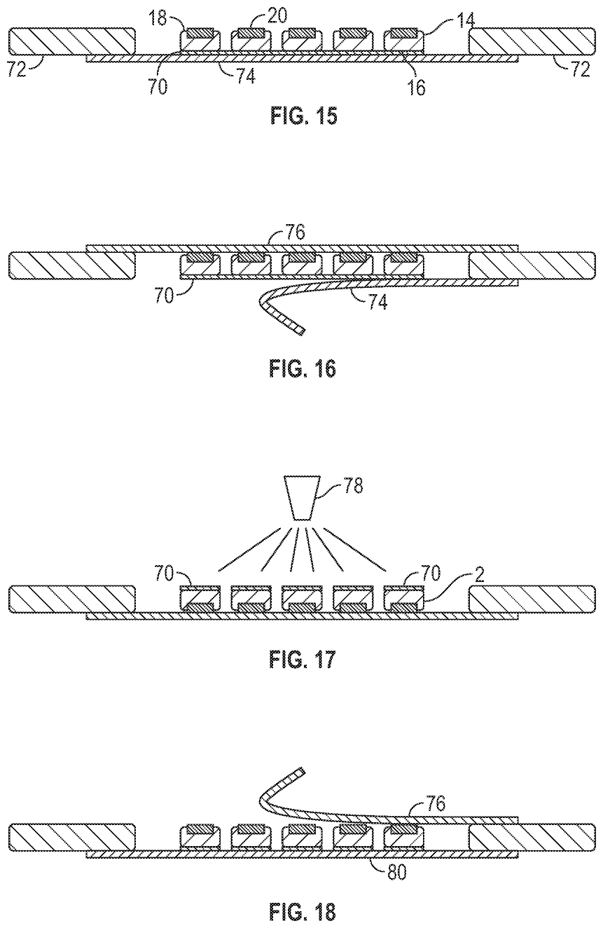

Referring to FIGS. 15-18, and reverting back to the backmetal examples of FIGS. 1-10, in various implementations a backmetal 70 deposited on a backside 16 of a wafer may include one of the intermediate metal layers 26, 28, 30, 32, 34, 36 described herein as well as the tin layer 48. As shown in FIG. 15 the wafer may be etched from the top side 18 (which in the implementation shown is a side including pads 20 which are not intended to be only used as grounds) using, by non-limiting example, SF6 plasma-based dry etching using the Bosch process or Time Division Multiplex (TDM) etching after selected portions of a passivation layer are removed. The passivation layer in implementations may be any disclosed in this document. The plasma etching may result in narrow scribe grids as low as 15 microns in thickness and may also allow no mechanical damage to die edges (such as chips or cracks), increased die per wafer, shaped die, keyed die, rounded corners, and increased die singulation throughput.

As seen in FIG. 16 a first tape 74 which coupled the backmetal 70 to a frame 72 during the singulation process may be removed after a second tape 76 is applied to the top sides 18 of the singulated die 14 and to the frame 72. By non-limiting example, the first tape 74 (and also the second tape 76 and later described third tape 80) may be ultraviolet (UV) tape that may be more easily removed after UV irradiation of the tape. The film frame 72 may be flipped so that a water jet 78 is positioned as shown in FIG. 17, and the water jet 78 is used to spray water onto the backmetal 70 in a process known as backmetal jet ablation to remove portions of the backmetal that correspond with the scribe grids or streets described above, singulating the backmetal 70 and forming a plurality of semiconductor packages 2, 4, 6, 8, or 10. The film frame 72 spins during this process while the water jet 78 nozzle swings from side to side to get complete coverage and therefore removal of all the backmetal 70 corresponding with the scribe grids or streets. In various implementations, one or more liquids other than water could be used. As shown in FIG. 18 the frame 72 may then be flipped again, a third tape 80 may be applied to the backmetal 70 side of each die 14, and the second tape 76 may be removed, for further processing, such as an optional wafer wash. The singulated units including die 14 and intermediate metal layers 26, 28, 30, 32, 34, or 36, and tin layer 48, are then ready for the reflow processes described above. Naturally, the flip chip example given in FIGS. 11-12 does not involve this type of backmetal processing. The removal of backside metallization using a wafer wash tool allows the use of dry die singulation using plasma etch, as described above, for narrow streets and other benefits, to be used, while using another process for singulating the backmetal 70. This may be useful in circumstances wherein the backmetal 70 either takes a relatively long amount of time to be singulated using the dry plasma etch process or otherwise cannot be removed using the dry plasma etch process. Jet ablation can also be used even where there is exposed Sn provided proper processing conditions exist.

In implementations the substrate 50 need not have a silver layer 52, and the sublayers 38 themselves may have all of the silver and/or copper needed to form the desired intermetallics of intermetallic layers 56, 58, 60, 62, or 64.

Solder paste or solder preform process results do not suggest the use of the backmetal devices and the flip chip devices disclosed herein. The vast majority of die attach processes incorporate the addition of a solder paste or solder preform to add solder between the die and the bonding surface. Generally, had various processing advantages, including: such a process requires only the die surface and the bonding surface to be solderable (in other words, it is easier to produce a wafer with a backmetal that is simply solderable than a backmetal which is solderable and also the solder itself); more flexibility is allowed for the die attach material (i.e., different pads could be soldered using different types of paste or preform, if desired—which cannot easily be accomplished when the solder is laid down as a backmetal across the entire wafer); and thicker connections may be made with solder paste or preforms, generally, for when thermally induced stresses are a potential problem (such as with plastic packages). Also, attempts to use backmetal structures including layers arranged into a titanium/nickel/tin structure used in the industry to replace solder paste have demonstrated stresses that are too high due to the thick nickel layer, observed at deposition and/or at elevated temperatures including future reflows, which can cause line down problems at the end customer assembly site. In these attempts, the thick nickel layer was required, or in other words, the nickel layer thickness was increased in this titanium/nickel/tin structure, to account for tin diffusion to the nickel layer and the formation of nickel-tin intermetallics. What was observed is that the nickel integrity was limited as the nickel was consumed to form nickel-tin intermetallics, which compromised the die shear strength. Additional observations indicated that with previous thick nickel backmetal structures there was also a long deposition process to lay down the layers, and a higher cost, in general, when compared to using solder paste. These recognized advantages and disadvantages of various processes known to those of ordinary skill would not lead them to investigate non-solder paste/solder preform processes involving nickel and other backmetal intermetallics using just the backmetal or bump materials for soldering.

In implementations the packages 2, 4, 6, 8, 10, 12 are designed specifically for lower stress applications such as where the substrate 50 is part of a ceramic board. There may be additional advantages of the packages and methods disclosed in this document. The method implementations disclosed herein may permit extremely small die to be bonded. For example, a die that is about 200 microns by about 200 microns in area (or about 220 microns by 220 microns) can, if bonded using an ordinary dispensed volume of solder, result in die tilt, movement from target location (die float), and the like, during die bonding. Such negative aspects for such small die generally may not occur with the methods disclosed herein.

With regards to the flip chip structures and methods disclosed herein, various flip chip bump structures are mounted to a board or substrate using solder paste, such as tin-lead or copper-tin-silver solder paste, to aid in the isolation of the die from stresses of the board or substrate. Sometimes large amounts of solder are used. Intermetallics are formed using such solder pastes, during the reflow process, but the flip chip bump structures will still melt during subsequent reflow processes due to the large amount of solder. This is actually by design so that the flip chip devices can be reworked or replaced if they are found to be faulty. Accordingly, ordinary flip chip processing using solder paste does not suggest using the bump material itself to attach the die to the substrate to those of ordinary skill.

Semiconductor packages 2, 4, 6, 8, 10, 12 in implementations may be used, as discussed above, in light emitting diode (LED) applications. In implementations they may also be used for non-LED applications which involve mounting a die to a ceramic substrate (such as, by non-limiting example, mounting a die to a substrate 50 of a ceramic substrate). In implementations they may also be used for applications which involve mounting a die to a non-ceramic substrate, such as, by non-limiting example, a leadframe, an organic substrate, and any other substrate type not containing a ceramic material.

In implementations the backmetal examples described herein may be used for light emitting diode (LED) semiconductor packages and may allow a lower cost than some backmetal materials which can include backmetal structures of titanium/nickel/gold-tin layers arranged in that order (in some cases of which the gold-tin layer is 3 microns thick), which result in a materials savings of over 77% over ordinary wafer back metal cost. The use of the materials disclosed herein may also reduce processing costs by allowing lower cost evaporation techniques instead of more costly sputtering techniques for applying layers. The gold-tin layer of the ordinary titanium/nickel/gold-tin example has gold and tin in the ratio of 80/20 (weight ration) and melts at 280 degrees Celsius, which is higher than the standard 260 degrees Celsius reflow profile used for subsequent devices added to a board or substrate. The flip chip examples described herein may also be used for LED semiconductor packages wherein the elimination of wire bonds will prevent light from being blocked by the wire.

The various implementations disclosed herein have focuses on die and flip chip applications of the liquid metal bonding methods and systems disclosed. These principles may also be applied to bonding various electrical interconnects as will be described further herein using the same types of metal layers, intermediate metal layers, and sublayers disclosed herein. The electrical interconnects may be, by non-limiting example, pins, clips, leads, compliant interconnects, guides, or any other electrical interconnect type used in a semiconductor package.

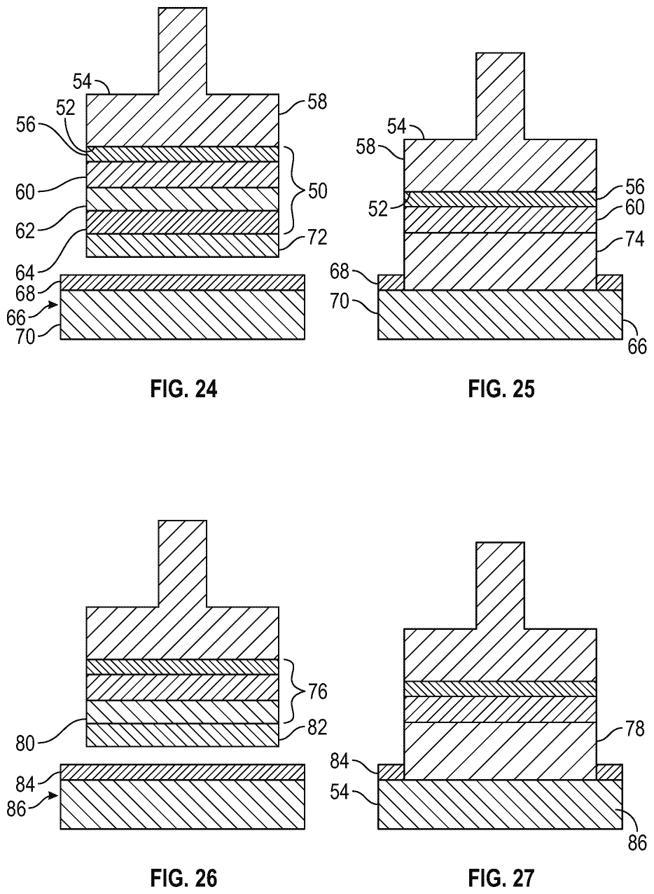

Referring now to FIGS. 24-25, in various implementations of a method of bonding an electrical interconnect to a substrate the method includes forming an intermediate metal layer 50 onto an end 52 of an electrical interconnect 54 (in this case a pin). Note that in the implementation the pin 54 includes a base 58. The intermediate metal layer 50 includes a plurality of sublayers. A first sublayer 56 including titanium (titanium sublayer) is deposited directly onto the base 58. A second sublayer including nickel (nickel sublayer) 60 is deposited directly onto the titanium sublayer 56. As used herein, “deposition directly onto” the titanium sublayer is meant to include any deposition onto an unoxidized/unreduced titanium sublayer as well as deposition onto an oxidized or otherwise reduced film of the titanium sublayer 56 formed prior to the deposition of the nickel sublayer 60 thereon (this same meaning is intended throughout this document whenever one layer is deposited “directly” onto another). A sublayer 62 including copper (copper sublayer) is deposited directly onto the nickel sublayer 60. A sublayer 64 including silver (silver sublayer) is deposited directly onto the copper sublayer 62. In various implementations each sublayer disclosed herein is formed of at least 50 wt. %, at least 80 wt. %, at least 85 wt. %, at least 90 wt. %, at least 95 wt. %, at least 96 wt. %, at least 97 wt. %, at least 98 wt. %, and/or at least 99 wt. % of the metal after which it is named. The deposition method for any of the sublayers may be any method disclosed in this document.

The substrate 66 includes a silver layer 68 atop a copper layer 70 and a bottom tin layer 72 on the base 58 of the pin 54 is reflowed with the silver layer 68 using a 260 degrees Celsius reflow profile, such that the silver sublayer 64 and copper sublayer 68 also diffuse/intermix sufficiently for the silver of the silver sublayer 64 and copper of the copper sublayer 68 to mix with the tin of the tin layer 72 to form intermetallics of tin, silver and/or copper. The tin layer 72 is pure tin or substantially pure tin and melts at 231 degrees Celsius and wets well to the substrate 66 with minimum voiding. The presence of silver and copper, even in small amounts, with the molten tin, results in the formation of intermetallics of one or more of silver, tin and/or copper fairly quickly, the intermetallics having melting temperatures (i.e., liquidus temperatures) greater than that of tin, which prevents or helps to prevent the flow of tin across the substrate 66 laterally. As previously discussed in this document with reference to the phase diagrams of FIGS. 13 and 14, the effect of the creation of the intermetallics is to create a phase in the intermetallic layer that has a melting temperature higher than 260 C.

Referring to FIG. 25, the raising of the melting temperature of the intermetallic layer 74 thus results in an electrical interconnect structure which will not reflow and/or re-melt during subsequent temperature increases when other devices are being reflowed or otherwise attached to the substrate 66 using a 260 C reflow profile. The properties of the intermetallic layer 74 thus produce a “single reflow” package or, in other words, the intermetallic layer 74 is a “single reflow” layer that will only reflow once under a 260 C reflow profile. This allows the pin 54 to stay in place during subsequent reflows when other devices/pins/electrical interconnects are mounted to the board of which the substrate 66 is a part. Various ordinary backmetal layers of titanium/nickel/gold-tin described more below, and other ordinary backmetal materials, do not have an increased melting temperature after the first reflow, but are susceptible to reflowing again when experiencing the same reflow profile temperature.

In terms of actual localized composition, there may be many different intermetallics or intermetallic compounds within the intermetallic layer 74 which may include any intermetallics including two or more of silver, tin and/or copper, though the intermetallic layer 74 may also be partially in the form of a solution. In other words, there may be some pure tin, some pure copper, some pure silver, some pure nickel, and so forth, in solution, with some intermetallics interspersed throughout, such as precipitated intermetallic crystals in solid solution, and/or there may be planar intermetallic layers particularly at boundary points (such as the boundary of the intermetallic layer 74 with the copper layer 70 and with the copper sublayer 62 (or the bottommost sublayer after reflow in the other examples described herein), without the entire intermetallic layer 74 being composed of intermetallics of two or more of silver, tin and/or copper. Nevertheless the intermetallic layer 74, due to the presence of the intermetallics in the layer, ultimately has a melting temperature greater than 260 C so that it does not reflow during subsequent high temperature processes that will include raising the temperature of the substrate 66 and/or any semiconductor package in which the substrate is included to, or to about, 260 C.

The final composition of intermetallics in the intermetallic layer 74 may vary between a wide range since, as shown with the phase diagrams of FIG. 13-14, only just above 2 weight percent copper or 4 weight percent silver needs to be mixed in with the tin to raise the melting temperature of the overall mixture above 260 degrees Celsius and, when more silver or copper are added, the melting temperature continues to increase.

The layers of the structure of FIG. 24 may have the following thicknesses. The titanium sublayer 56 may be, or may be about, 1.15 kiloAngstroms (kÅ) thick, though a wide range of thicknesses could be used. This sublayer may or may not be used in various pin implementations. In other implementations, the material of the titanium sublayer may be replaced with other materials such as titanium-tungsten (TiW), chromium (Cr), nickel-chromium (NiCr), and the like. The nickel sublayer 60 may be, or may be about, 1 kÅ to about 6 kÅ. In particular implementations it may be 5 kÅ. This layer may be thicker for higher temperature applications (such as for high temperature storage requirements for hotter light emitting diodes (LEDs)), or when the tin layer 72 is thicker so that there is less of a risk of much or most (or all) of the nickel being consumed into nickel-tin intermetallics which is generally undesirable, and/or when the substrate 66 does not include a silver layer 68 to consume some of the tin into silver-tin intermetallics thereby reducing the formation of nickel-tin intermetallics. Too thick of a nickel sublayer 60 may result in excessive stresses. The copper sublayer 62 may be, or may be about, 4 kÅ thick, and in implementations may range from 0.1 kÅ to 12 kÅ. The silver sublayer 64 may be, or may be about, 2 kÅ thick, and in implementations may range between 0.5 kÅ and 12 kÅ or between 0 kÅ and 12 kÅ (in some implementations, as described herein, there is no silver sublayer 64 at all). In implementations the tin layer 72 may be, or may be about, 16 kÅ thick, and in implementations may range from 10 kÅ to 30 kÅ.

The ratio of silver to tin can be adjusted based on the application and the type of electrical interconnect being liquid phase bonded to the substrate 66. Increasing the thickness of the tin layer 72 allows for additional or enhanced wetting to substrate 66 and reduction of voids if the surface of the substrate 66 is rough. Increasing the thickness of the silver sublayer 64 increases protection of the nickel (i.e., preventing the nickel from being consumed into nickel-tin intermetallics). It can, however, be desirable that some of the nickel, but not all of the nickel, be consumed in nickel-tin intermetallics. Accordingly, if the silver sublayer 64 is too thick, this can restrict the amount of nickel-tin intermetallics too much and can actually reduce the shear strength and consistency of the pin-substrate bond. The ratio of silver to tin may thus be adjusted so that the desired silver-tin intermetallics in the desired amount are formed during reflow. The ratio of copper to tin can also be adjusted based on the particular electrical interconnect being bonded. Increasing the thickness of the copper sublayer 62 allows for a thicker tin layer 72 because a thicker copper sublayer 62 better slows down or impedes the formation of nickel-tin intermetallics.

As can be seen from comparing FIG. 25 to FIG. 24, the tin layer 74, silver layer 68 of the substrate 66, silver sublayer 64, and copper sublayer 62 may be consumed in the intermetallic layer 74. The use of the sublayers 50 and tin layer 74 may also allow for adhesion of the pin 54 to the substrate 66 without the use of solder paste or preforms. The copper layer 70 and the portion of the copper sublayer 62 that remains may provide solderable surfaces for the tin and intermetallics and other elements of the intermetallic layer 72. In implementations the copper of the copper layer 70 of the substrate 66 may also form intermetallics with the tin of the tin layer 72, further providing a strong die attach and reducing the amount of nickel-tin intermetallics by consuming some of the tin into tin-copper intermetallics.

FIGS. 26-27 illustrate an implementation of a similar materials system for an electrical interconnect to that shown in FIGS. 24-25 but with a set of metal sublayers 76 that does not include a silver sublayer 64. The remaining sublayers may have the same thicknesses and material types described previously. The processes and results of the bonding are similar to those described previously, except that the resulting intermetallic layer 78 may include somewhat different overall percentages of silver, copper and tin and therefore may have different intermetallics and/or different amounts of different intermetallics and different amounts of metals or compounds precipitated or in solution, etc. Nevertheless, intermetallic layer 78 likewise has a melting temperature greater than 260 C and the pin-substrate bond otherwise generally has similar single-reflow properties as those described above with respect to pin 54. As can be seen by comparing FIG. 26 to FIG. 27, the copper sublayer 80, tin layer 82, and the silver layer 84 of the substrate 86 may be fully or partially consumed in the intermetallic layer 78.

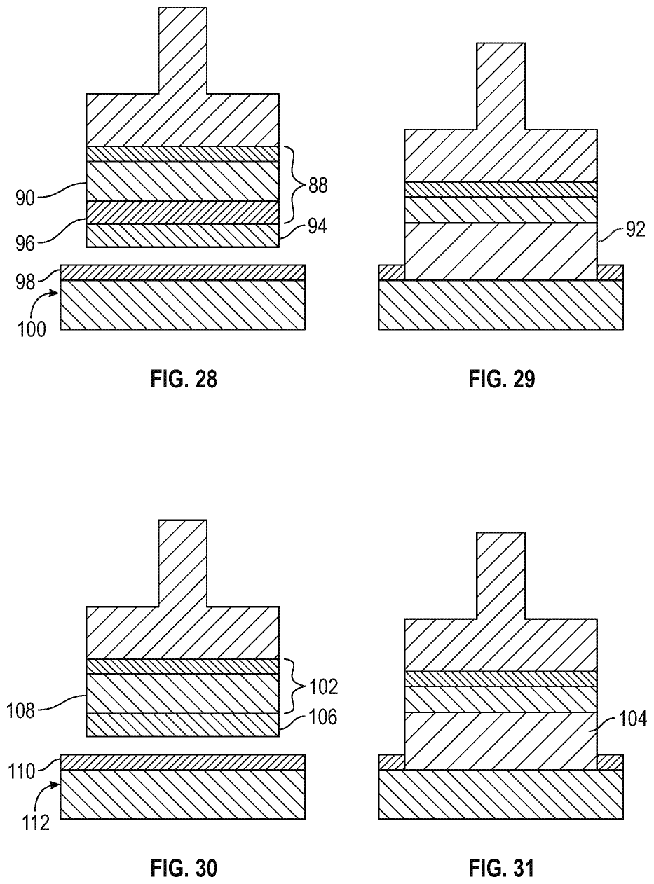

FIGS. 28-29 illustrate an implementation of a similar materials system for an electrical interconnect to that shown in FIGS. 24-25 but with a set of metal sublayers 88 that does not include a nickel sublayer 60. The remaining layers may have the thicknesses described above, though in implementations the thickness of the copper sublayer 90 may range between 1 kÅ and 40 kÅ. The processes and results are similar to above, however, except that the intermetallic layer 92 may have somewhat different overall percentages of silver, copper and tin and therefore may have different intermetallics and/or different amounts of different intermetallics, different amounts of metals or compounds precipitated or in solution, etc. Nevertheless, intermetallic layer 92 has a melting temperature greater than 260 C and the pin-substrate bond otherwise generally has similar single-reflow properties as those described above with respect to pin 54. As can be seen by comparing FIG. 28 to FIG. 29 the tin layer 94, silver sublayer 96, a portion of the copper sublayer 90, and the silver layer 98 of the substrate 100 may be consumed in the intermetallic layer 92.

FIGS. 30-31 illustrate an implementation of a similar materials system for an electrical interconnect to that shown in FIGS. 24-25 but with a set of sublayers 102 that does not include a nickel sublayer 60 or a silver sublayer 64. The remaining sublayers may have the thicknesses and materials described above. The processes and results of the bonding are similar to those described previously, however, except that the intermetallic layer 104 may include somewhat different overall percentages of silver, copper and tin and therefore may have different intermetallics and/or different amounts of different intermetallics, different amounts of metals or compounds precipitated or in solution, etc. Nevertheless, the resulting intermetallic layer 104 has a melting temperature greater than 260 C and the pin-substrate bond otherwise generally has similar single-reflow properties as those described above with respect to pin 54. As can be seen by comparing FIG. 30 to FIG. 31, the tin layer 106, a portion of the copper sublayer 108, and the silver layer 110 of the substrate 112 are fully or partially consumed in the intermetallic layer 104.

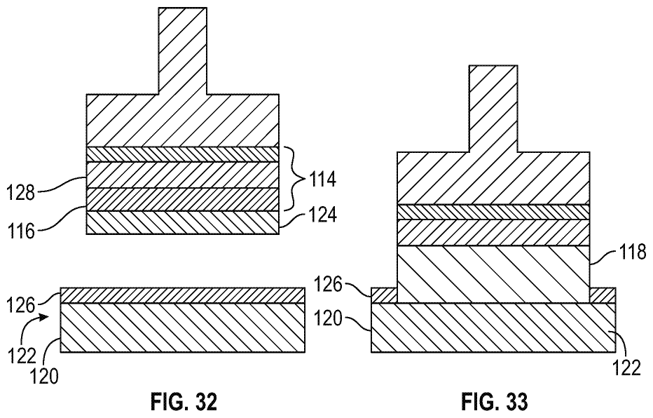

FIGS. 32-33 illustrate an implementation of a similar materials system for an electrical interconnect to that shown in FIGS. 24-25 but with a set of metal sublayers 114 that does not include a copper sublayer 62. The remaining sublayers may have the thicknesses described above, though in implementations the silver sublayer 116 may have a thickness of 4 kÅ and may range between 1 kÅ and 12 kÅ. The processes and results of the bond are similar to above, however, except that the intermetallic layer 118 may have somewhat different overall percentages of silver, copper and tin and therefore may have different intermetallics and/or different amounts of different intermetallics, different amounts of metals or compounds precipitated or in solution, etc. In particular, since there is no copper sublayer 62, and although there may be some copper in the intermetallic layer 118 from the copper layer 120 of the substrate 122, the intermetallics of the intermetallic layer 118 may predominantly comprise intermetallics of silver and tin. Intermetallics of copper and tin may form at the interfaces of the intermetallic layer 118 and the copper layer 120 of the substrate 122, though in various implementations. Intermetallic layer 118 also has a melting temperature greater than 260 C and the pin-substrate bond otherwise generally has similar single-reflow properties as those described above with respect to pin 54. As can be seen by comparing FIG. 32 to FIG. 33 the tin layer 124, silver sublayer 116, and the silver layer 126 of the substrate 122 may be consumed in the intermetallic layer 118 during reflow. The silver sublayer 116 between the nickel sublayer 128 and the tin layer 124 impedes the diffusion of the tin with the nickel and limits the formation of nickel-tin intermetallics, which may allow for a stronger die bond or solder joint.

The materials systems of FIGS. 32 and 33 could in some implementations experience problems with all or substantially all of the nickel being consumed into nickel-tin intermetallics if too thick a tin layer 124 is included. By non-limiting example, in various implementations a thicker tin layer 124 may be needed for reflowing onto rougher substrates 122 (such as rougher ceramic substrates), when the substrate 122 is not a part of a ceramic substrate, when less voiding is required, or when a taller solder joint is needed for increased reliability. In such instances the ratio of tin to silver is increased, and in such instances the implementations of FIG. 24, 25, 28 or 30 may be used instead which either do not include a nickel sublayer 60 or includes a copper sublayer 62 between the tin layer 72 and the nickel sublayer 60 in order to prevent or hinder the formation of nickel-tin intermetallics (by consuming some of the tin into tin-copper intermetallics and referring to FIG. 24). The reduction of nickel-tin intermetallics may result in a stronger die bond/solder joint. Some nickel-tin intermetallics can be desirable and show good wetting and adhesion during reflow but when all of the nickel is consumed by the tin into nickel-tin intermetallics so that there is no longer any pure nickel remaining then the adhesion is generally decreased and the shear strength of the pin-substrate bond reduced.

In various implementations the various substrates may not have a silver layer thereon, and the set of sublayers associated with the electrical interconnects themselves may have all of the silver and/or copper needed to form the desired intermetallics of intermetallic layers.

In implementations the liquid phase bonding process disclosed previously is designed specifically for lower stress applications such as where the substrates are is part or include a ceramic component. The use of the liquid phase bonding may extremely small electrical interconnects to be bonded. For example, an interconnect that is about 200 microns by about 200 microns in bonding area with the substrate (or about 220 microns by 220 microns) would, if bonded using an ordinary dispensed volume of solder, result in tilt, movement from target location (float), and the like, during bonding if ordinary soldering processes disclosed herein were attempted. Such negative aspects for such small interconnects generally may not occur with the methods disclosed herein. In implementations the liquid phase bonding process may also be used for applications which involve mounting an electrical interconnect to a non-ceramic substrate, such as, by non-limiting example, a leadframe, an organic substrate, and any other substrate type not containing a ceramic material.

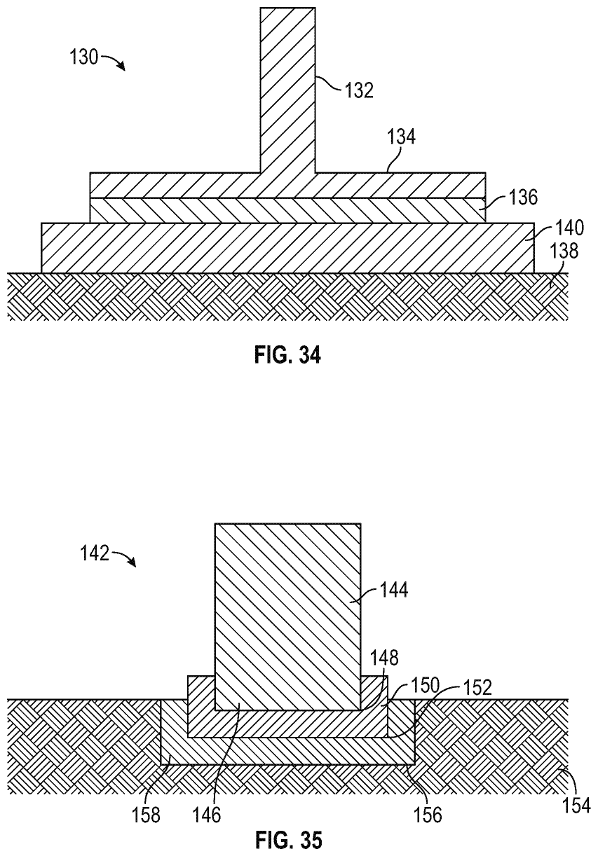

Referring to FIG. 34, an implementation of a pin-substrate system 130 is illustrated where a pin 132 includes a base 134. Directly coupled to the base 134 is a first metal layer 136. Directly coupled to substrate 138 is a second metal layer 140. In FIG. 34, the pin 132 is resting on the second metal layer 140 of the substrate 138 prior to heating to form liquid bond. In some implementations, a jig or fixture (not shown in FIG. 34 may be used to hold the pin 132 in place during the heating and subsequent cooling operation that forms the bond. In other implementations, a flux or other temporary material may be used to hold the pin in place while it is being transported to the heating apparatus and gravity force may be sufficient to hold the base of the pin in place during the liquid phase bonding process until sufficiently cooled to hold the pin in place. The first metal layer 136 may include any of the metal sublayers disclosed herein previously in FIGS. 24-33 associated with a pin. The second metal layer 140 may include any of the metal sublayers associated with a substrate disclosed herein previously with respect to FIGS. 24-33. The substrate may be any substrate type disclosed herein. Here the use of the various combinations of sublayers work to prevent subsequent heating steps during package formation from causing floating or tilting of the pin as the reflow temperature of the resulting intermetallic layer(s) formed during the initial heating step is greater than 260 C.

Referring to FIG. 35, another implementation of a pin-substrate system 142 is illustrated. Here pin 144 does not include a base structure, but the end 146 of the pin 144 is a rod with a substantially perpendicular edge 148 (corner). In various implementations, the cross sectional shape of the end 146 of the pin may be, by non-limiting example, rectangular, circular, elliptical, triangular, or any other closed shape. In various implementations, the end 146 of the pin 144 may form a prism having any of the previously mentioned cross sectional shapes. As illustrated in FIG. 35, a first metal layer 150 is directly coupled over the end 146 of the pin including over/around the substantially perpendicular edge 148, causing the first metal layer 150 to have a corresponding substantially perpendicular edge 152. Substrate 154 includes opening 156 therein and the shape of opening 156 corresponds with the shape of the first metal layer 150 so as to allow the first metal layer and the end 146 of the pin 144 to be inserted therein. Inside opening 156 is a second metal layer 158. In various implementations, the first metal layer 150 may include any of the metal sublayers disclosed herein previously with respect to FIGS. 24-33 associated with a pin. In various implementations, the second metal layer 158 may include any of the metal sublayers disclosed herein previously with respect to FIGS. 24-33 that are associated with a substrate.

Because the end 146 of the pin 144 can be inserted into the opening 156 to a predetermined depth and because of a tolerance between the first metal layer and the second metal layer, the pin 144 may be held in the opening 146 during the subsequent heating and bonding process without the use of a jig or fixture in some implementations. In others, a jig or fixture is used to hold the pin 144 in place to ensure the pin is in the desired orientation relative to the substrate 154 following the completion of the liquid bonding process. As previously discussed, the resulting intermetallic layer(s) formed during the liquid bonding operation will result in the intermetallic material have a melting temperature greater than 260 C, thus permitting additional heating operations to be carried out without causing floating or tilting of the pin. The ability to not use a base associated with the pin in combination with a corresponding opening in the substrate may allow for reduced pin pitch and thus greater interconnect density. It may also result in smaller a smaller package size because space does not have to be provided to accommodate the electrical isolation spacing needed to space pins with bases.

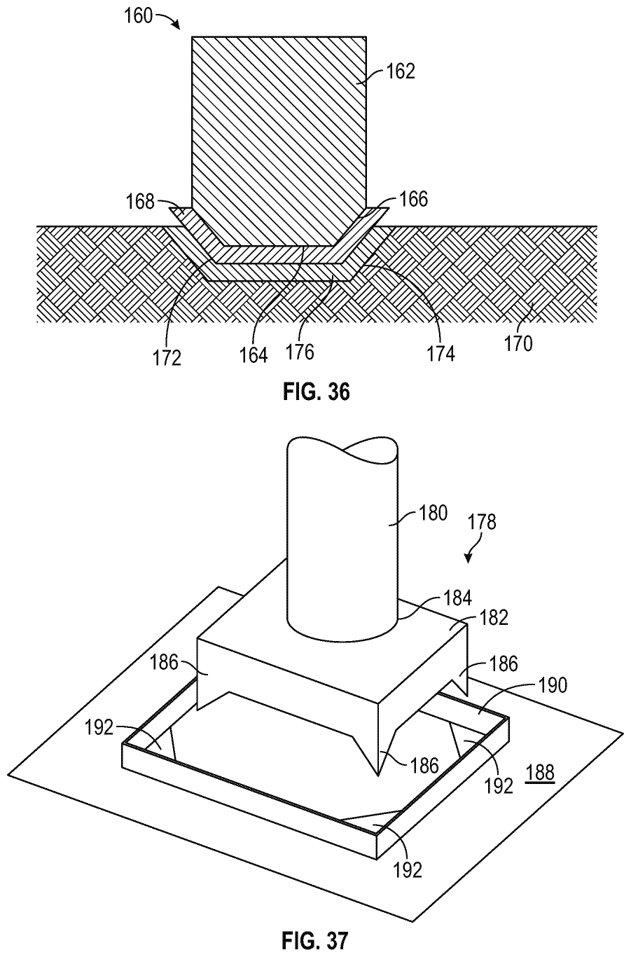

Referring to FIG. 36, another implementation of a pin-substrate system 160 is illustrated. Like the pin of FIG. 35, the pin 162 has an end 164 which does not include a base structure but includes, by non-limiting example, a beveled edge, a chamfered edge, or an angled edge. In the implementation illustrated in FIG. 35, the end 164 includes an angled edge 166 that extends around the pin 162. The end 164 of the pin 162 may be, in various implementations, a prism with any of the previously disclosed cross sectional shapes. As illustrated, the end 164 of the pin 162 includes a first metal layer 168 directly coupled thereto and the first metal layer 168 includes a corresponding angled edge 172. Substrate 170 includes opening 174 therein that has a shape that corresponds with the angled edge 172 of the first metal layer 168. Opening 174 includes second metal layer 176. Similar to the implementation of FIG. 35, the first metal layer 168 may include any of the sublayers associated with a pin disclosed in FIGS. 24-33 and associated disclosure and the second metal layer 176 may include any of the metal sublayers associated with the substrates disclosed in FIGS. 24-33. The resulting intermetallic layer(s) following liquefaction to form a bond demonstrating a subsequent melting temperature greater than 260 C. As with the implementation in FIG. 35, depending on the depth of the opening 174 into the substrate 170 and the tolerance between the first metal layer 168 and the second metal layer 176, the bonding process may take place following insertion of the pin 162 into the opening 174 without the use of a jig or figure in some implementations. In other implementations a jig or figure is used to hold the pin 162 in place until the liquid bond has solidified. Like the implementation of FIG. 35, the end 164 of the pin 162 of FIG. 36 does not use a base, thus allowing for decreasing pin pitch accordingly and the potential for corresponding package size reduction.

While the pin implementations of FIGS. 35 and 36 include a single opening designed to receive the end of the respective pins 144, 162, in other implementations, more than one opening may correspond with each pin. Referring to FIG. 37, a pin-substrate system 178 in an perspective exploded view is illustrated. Here the pin 180 includes a base 182 coupled to the end 184 of the pin. The base 182 includes projections 186 (four in this implementation) that each have the shape of a right triangular pyramid. Substrate 188 is illustrated in partial see-through view showing opening 190 that extends into the material of the substrate 188 and also includes additional corresponding openings 192 that are designed to receive the projections 186 when the base 182 is inserted into opening 190. A first metal layer (not shown for purposes of simpler illustrating in FIG. 37) is included on the surface of the base 182 and a second metal layer (also not shown for purposes of illustration) is included in opening 190. The first metal layer and second metal layer may be any set of metal sublayers associated with a pin and substrate, respectively disclosed herein in various implementations. Where the base with the projections is employed, in some implementations, no jig or fixture may be needed depending on the tolerances during the liquid phase bonding process. In other implementations, a jig or fixture may be employed to hold the pin 180 in a desired orientation during the bonding process.

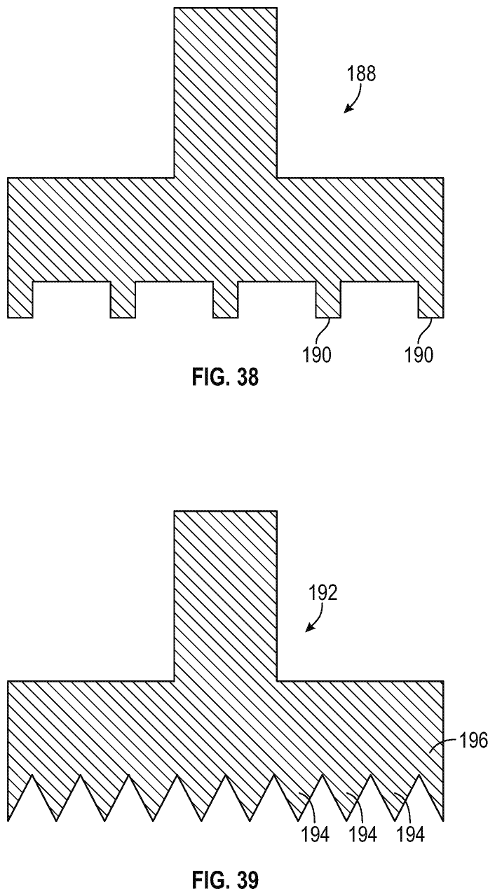

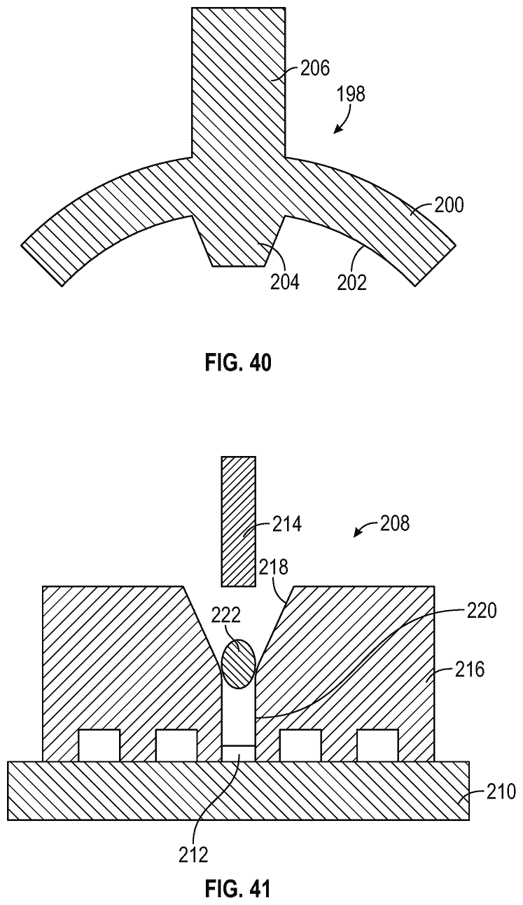

While the use of right triangular projections 186 is illustrated in the pin implementation, FIG. 38 is a cross sectional view of another pin and base implementation 188 that includes rectangular solid projections 190 each designed to fit into corresponding openings in a substrate and which are coated with a first metal layer like those disclosed herein. The projections may also be pyramidal in various implementations like the implementation illustrated in FIG. 39 that shows a pin-base system 192 with such projections 194 distributed across the entire surface of the base 196. In other implementations, other solid shapes may be employed for the projections including, by non-limiting example, a cone, a conical frustum, or any other solid shape/type. While the use of a base that has a planar surface has been illustrated in FIGS. 37-39, the base may be an angled or curved surface as in the pin-base system 198 of the implementation illustrated in FIG. 40. Here the base 200 includes a curved surface 202 with a centered projection 204 therein designed to engage into corresponding openings in a substrate and aid in stabilizing the pin 206 while forming liquid phase bonds. In all of the pin implementations illustrated in FIGS. 37-40 a jig or fixture may or may not be used during the bonding process. Also, in all the pin implementations of FIGS. 37-40 the use of first metal and second metal layers on the base and opening portions like those disclosed herein is used while the structure of the metal layers is omitted for easier illustration of the projection structure.

In all of the foregoing pin-substrate systems where openings in the substrate are employed, the pin and opening may work together to form a self-aligning pin-substrate system. This ability of the pins to self-align with the holes may increase process margin particularly where pin pitch is decreased. The various principles disclosed herein that are used with pins can also be used with other electrical interconnect types like clips.

Referring to FIG. 41, another implementation of a pin-substrate system 208 is illustrated. In this implementation, the system 208 includes substrate 210 to which pad 212 has been coupled which is ready to be bonded to pin 214. Mold compound or housing 216 has been coupled to substrate 210 and includes well opening 218 and pin guide portion 220. A portion of solder or other bonding compound 222 is held in the well opening 218 prior to heating of the substrate 210 during the liquid phase bonding. During heating of the substrate 210, the portion 222 melts and runs down into the pin guide portion 220 as the pin 214 is then inserted into the pin guide portion 220 until the end of the pin 214 reaches the pad 212. The substrate is then allowed to cool so the bond between the pin 214 and the pad 212 is completed. Because of the use of the well opening 218 and the pin guide portion 220, depending on the tolerance between the pin 214 and the pin guide portion 220, no jig or fixture other than the pin guide portion 220 may be needed. Furthermore, the use of a wide variety of solders and other heat flowable materials can be used in implementations with the design illustrated in FIG. 41 including those with melting temperatures below 260 C because the pin guide portion 220 can prevent subsequent float and/or tilt of the pin during subsequent heating steps. Thus implementations like those in FIG. 41 may not employ the various metal sublayer combinations between pin and substrate previously disclosed in some implementations. In other implementations, the metal sublayers may be applied to the pin and the substrate sublayers may be included in the portion 222 and/or the portion 222 and the pad 212. Many different shapes for the well portion 218 and pin guide portion 220 are possible using the principles disclosed herein. In various implementations, the portion 222 may be placed in the well opening 218 using, by non-limiting example, a screen printing, solder dispensing, or metal jet printing method. In some implementations, nickel present on the substrate may be utilized in the pad 212 which may be nickel present since the substrate was formed. In other implementations, the nickel may be added to the substrate as a final step just prior to forming the encapsulating material to help minimize nickel oxide formation.

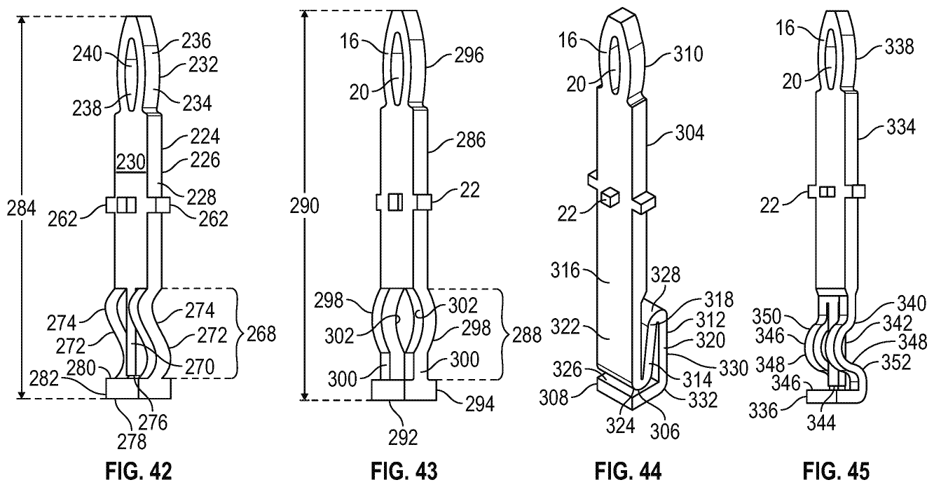

In any of the pin-substrate system implementations disclosed herein, numerous different pin implementations may be used that form the structure of the end of the pin opposite the end bonded to the substrate. FIGS. 42-45 and 48 are non-limiting examples of pin types that could be employed where the pin employs a base. Other pin designs could be used where the pin does not use a base. Any of the pin designs found in U.S. Pat. No. 9,620,877 to Yao et al, entitled “Flexible Press Fit Pins for Semiconductor Packages and Related Methods,” App. Ser. No. 14/703,002, filed May 4, 2015 and issued Apr. 11, 2017, the disclosure of which is incorporated entirely herein by reference, could be employed in various pin-substrate systems herein.

Referring now to FIG. 42, in various implementations a flexible press-fit pin (pin) 224 includes a body 226. In the implementations illustrated, this is a rectangular body 228 having a number of side surfaces 230. The pin 224 includes an upper contact portion 232 with contact surfaces 234 configured to electrically and physically couple with a pin receiver, such as a pin receiver of a motherboard, a printed circuit board (PCB), or another electrical component, or the like. The upper contact portion 234 includes deformable portion 236. A cavity 238 of the upper contact portion 234 provides room for the sidewalls 240 of the deformable portion to deform inwards when the upper contact portion is inserted into a pin receiver. The pin receiver generally will have a diameter slightly smaller than that of the pin so that the deformation occurs. This may include plastic deformation, though in implementations it could be only elastic deformation. The difference in size between the upper contact portion 232 and the pin receiver results in a friction fit between the two. Thus, when the upper contact portion of the pin 224 is inserted into a pin receiver, it is secured into place through the compressive forces between the contact surfaces 234 and the surface(s) of the pin receiver.

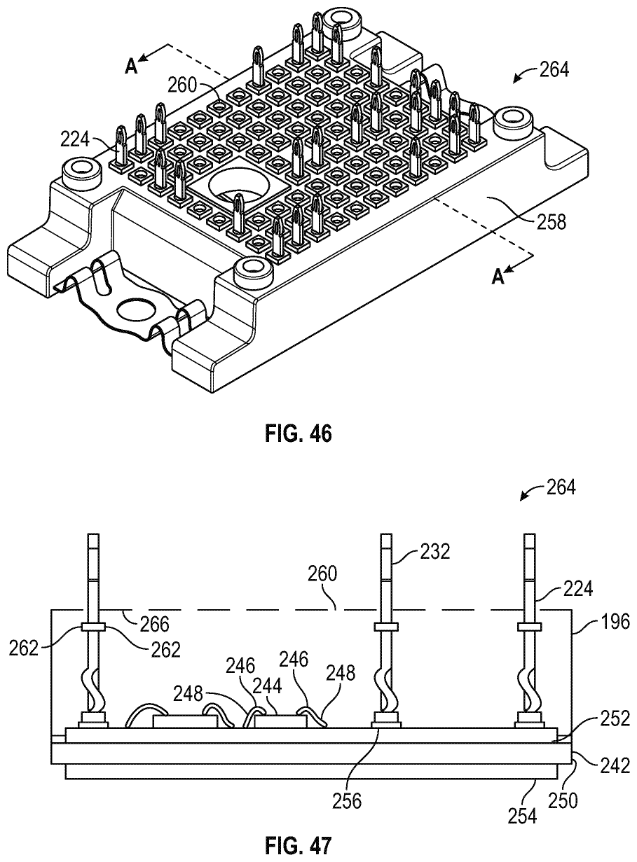

As shown in FIGS. 46-47, in use the pin is coupled with a substrate 242 and will be in electrical communication with one or more die 244 such as through electrical couplers 246 and/or through traces on an upper surface of the substrate. The electrical couplers may be wirebonds 248, clips, or other elements. The substrate shown in FIG. 47 is a direct bonded copper (DBC) substrate having a ceramic layer 250 sandwiched between a first copper layer 252 and second copper layer 254. Any other type of substrate could be used, however, instead of a DBC substrate. In the implementations shown the pin is coupled to the substrate using the various intermediate metal layers and metal sublayers 256 disclosed herein. In implementations in which the substrate is a DBC substrate the ceramic layer may include aluminum oxide.

Referring to FIG. 46, the casing implementation illustrate 258 at least partially encloses the substrate 242 and includes openings 260, each of which is sized sufficiently to allow an upper end of a pin 224 to extend therethrough. In other words, each opening 260 includes a diameter larger than a diameter of the upper contact portion 232. A number of stops 262 are included on each pin. In implementations each pin includes four stops, one on each side surface 230. In other implementations there could be fewer stops, such as only two on opposing side surfaces 230. Each stop 262 is a projection. The projection could have any closed three-dimensional shape. In the implementations shown they are cuboidal.

When semiconductor package (package) 264 is coupled with a motherboard, printed circuit board (PCB), or other component (such as by pressing the pins 224 into pin receivers of the motherboard, PCB, or other component), a flexible portion of each pin will flex to some degree, as will be described hereafter. Later, if the package 264 is removed from the motherboard, PCB or other component, the flexible portion will allow the pin to expand upwards so that the stops 262 approach the inner surface 262 of the casing 258. When the stops 262 contact the inner surface 262 the pin is then mechanically prevented from extending further upwards, which stops the pin from decoupling from the substrate at the solder point or other contact location. This may also prevent fracture of the pin bond. Package 264 is a power integration module (PIM), though in implementations it could be a package other than a PIM.

Referring to FIG. 42, a lower portion 268 of each pin 224 includes a vertical stop 270 between two curved legs 274. Each curved leg 274 includes an s-shape 272. The vertical stop 270 includes a bottom contact surface 276. The lower portion 268 is coupled with a base (horizontal base) 278 which includes a lower contact surface 278 configured to be coupled with a substrate, as described above, and an upper contact surface 280. There is a gap between the vertical stop and the base or, in other words, between the bottom contact surface 276 of the vertical stop 270 and the upper contact surface 280 of the base 282. When the pin is inserted into a pin receiver, as described previously, the pressure of pushing the pin therein may cause a compressive pressure on the pin along a longest length of the pin, and the curved legs 274 are configured to allow the pin to compress along this longest length and to allow some deformation of the pin. This may, by non-limiting example, allow the pin to absorb some of the pressure of installation of the module onto a motherboard, PCB or the like without imparting all of the pressure onto the substrate below. It may also permit deformation during thermal power cycling of the semiconductor package. This deformation or flexing may, in some implementations, be fully elastic though, in other implementations, it could be plastic deformation.

The vertical stop 270 prevents the pin from flexing downwards (or, in other words, compressing along the longest length of the pin) beyond a certain distance. When the vertical stop 270 contacts the base 282, by the bottom contact surface 276 of the vertical stop 270 coming into contact with the upper contact surface 280 of the base 282, the curved legs 274 then cease flexing or deforming further, so that the pin 224 stops flexing or deforming downwards (or, in other words, stops compressing along the longest length of the pin). During operation, the curved legs 274 are those that carry electrical current between the upper contact portion 232 and the base 268 of the pin 224. The vertical stop 270 generally does not carry current between the upper contact portion 280 and the base 282 of the pin 224 because, in general, the gap is present when the semiconductor package 264 is being used and, further, because there is a gap between each curved leg 274 and the vertical stop 270. Each pin 224 includes a longest length 284, measured from the lower contact surface 278 to the top of the upper contact portion 232.

In implementations when the pin 2 is viewed from the side (i.e., so that one curved leg is substantially hid, or is fully hid, behind the other curved leg) there are no gaps visible between the curved legs 274 and the vertical stop 270 apart from the gap between the bottom contact surface 280 of the vertical stop 270 and the upper contact surface 280 of the horizontal base 282.

Referring to FIG. 43, in various implementations, a flexible press fit pin (pin) 286 includes many elements in common with pin 224 and some different elements. Above the lower portion 288 the pin 286 is identical or substantially identical to pin 224. The pin 286 has a longest length 290 measured from a lower contact surface 292 of the base (horizontal base) 294 to the top of the upper contact portion 296 of pin 286. The main difference between pin 286 and pin 224 is the lower portion 288. Lower portion 288 includes a pair of partially curved legs 298. Each partially curved leg 298 includes a curve and terminates in a non-curved portion 300 coupled directly to the horizontal base. The non-curved portion 300 in each case is a vertical portion. When the pin 286 is viewed from the side (so that the non-curved portion of one partially curved leg is substantially hid, or is fully hid, behind the non-curved portion of the other partially curved leg), a gap is visible between the two curves. Thus the curves are curved in opposite directions and, therefore, form complementary opposing curves (curves) 302 curving away from a longest length of the pin 286. In some implementations, there need not be a gap visible when the pin 286 is viewed from the side, but there may be no visible gap or the pins may visually overlap when viewed from the side. The partially curved legs 298 are configured to deform in complementary opposing directions in response to a pressure applied to the pin 286 along a direction collinear with the longest length of the pin 286 toward the base 294.

When the pin 286 is being inserted into a pin receiver, such that there is pressure downwards on the pin (or, in other words, a compressive force along the longest length of the pin) the complementary opposing curves 302 are configured to bow outwards, to allow the pin to flex. This bowing movement may be purely elastic deformation or it may also include plastic deformation in some implementations. Pin 286 does not have a vertical stop as there is a space between the two partially curved legs instead of the vertical stop that is located in that place on pin 224. In other implementations, a vertical stop could be included in this space, similar to the vertical stop of pin 224. Both of the partially curved legs 298 are configured to conduct electricity between the upper contact portion and the base 294 of the pin 286 and, if a vertical stop were added, the vertical stop would generally not conduct electricity between the upper contact portion and the base of the pin, as has been described with respect to pin 224. As can be seen, each of the two partially curved legs 298 includes only a single curve that is concave relative to the single curve of the other of the two partially curved legs 298.

Referring to FIG. 44, in various implementations, a flexible press fit pin (pin) 304 includes many elements in common with pin 224 and some different elements. Above the lower portion the pin 304 is identical or substantially identical to pin 224. The pin 304 has a longest length measured from a lower contact surface 306 of the base (horizontal base) 308 to the top of the upper contact portion 310 of pin 304. The main difference between pin 304 and pin 224 is the lower portion. Lower portion includes, instead of multiple legs, a single leg 312 that is bent into an N-shape 314. The N-shape 314 includes a first substantially vertical section 316, a slanted section 318, and a second substantially vertical section 320, forming the N-shape. In various implementations, the first substantially vertical section 316 is not just substantially vertical, but is fully vertical. In other implementations, the second substantially vertical section 320 is not just substantially vertical, but is fully vertical. In particular implementations, the first substantially vertical section 316 is parallel with, or is substantially parallel with (or is in other words collinear with), the longest length of the pin.

Accordingly, the lower portion includes a first section 322 aligned with the longest length of the pin. A first bend 324 couples the first section 322 with the aforementioned slanted section 318. The first bend 324 is illustrated as being somewhat rounded, though in other implementations it could be more or less rounded and even sharp edged. A lower contact surface 306 of the first bend is configured to act as a stop, similar to the vertical stop of pin 224, when it contacts an upper contact surface 326 of the base 308. Thus, in general, when the pin 304 is in a relaxed configuration, there is a gap present between the upper contact surface 326 of the base and the lower contact surface of the first bend 324. When the pin is being inserted into a pin receiver or in other circumstances wherein there is a downwards pressure on the pin (or, in other words, a compressive force on the pin in a direction substantially parallel with the longest length of the pin), the gap narrows until, if enough pressure is applied, the lower contact surface 306 of the bend contacts the upper contact surface 326 of the base and prevents further downwards flexing (i.e., compression) of the pin. Thus the N-shape allows the pin some downward flexing (compression) but prevents movement beyond a certain distance. As described with respect to the other pins, this flexing may be fully elastic or, in various implementations, it could include plastic deformation.

as can also is illustrated in FIG. 7, the first section may form an angle of about three degrees to about thirty degrees with the slanted section through the first bend. In various implementations this angle may be an angle of, or of about, seven degrees. The second section may form an angle of about three degrees to about thirty degrees with the slanted section through the second bend. In particular implementations, this angle may be an angle of, or of about, seven degrees. The second section may make an angle of about sixty to one hundred and twenty degrees with the base through the third bend. In particular implementations, this angle may be, or may be about, ninety degrees. There is a second bend 328 that couples the slanted section 314 with the second section 330, and there is a third bend 332 which couples the second section 330 with the base 308.

Thus, the N-shape 314 is configured to flex to allow the lower contact surface 306 of the first bend 324 to move toward the upper contact surface 326 of the base 308 in response to a pressure applied to the pin 304 along a direction collinear with a longest length of the pin 304 toward the upper contact surface 326, and the N-shape 314 is further configured to stop flexing after it has bent sufficiently to allow the lower contact surface 306 of the first bend 324 to contact the upper contact surface 326 of the base 308.

Referring to FIG. 45, in various implementations a flexible press fit pin (pin) 334 includes many elements in common with pin 224 and some different elements. Above the lower portion the pin 334 is identical or substantially identical to pin 224. The pin 334 has a longest length measured from a lower contact surface of base 336 to the top of the upper contact portion 338 of pin 334. The main difference between pin 334 and pin 224 is the lower portion. Lower portion includes a structure which is somewhat similar, but differs in various respects from the lower portion 268 of pin 224.

Lower portion includes two curved legs 340 and a vertical stop 342. A bottom contact surface 344 of the vertical stop 342 faces an upper contact surface 346 of the base 336 and, as with the vertical stop of pin 222, is configured to prevent further downward flexing (i.e., compression, movement) of the pin 334 once the vertical stop 342 contacts the base 336. Thus, in an unflexed configuration, there is a gap between the vertical stop 342 and the base 336. The curved legs 340 are configured to flex, when a compressive pressure is applied on the pin 334 along the longest length of the pin 334 (such as during installation of the pin 334 into a pin receiver). This flexing may be fully elastic or, in implementations, may include plastic deformation. The lower portion of the pin 334 may also allow the pin to flex (i.e., expand) under a tensile pressure applied on the pin along the longest length of the pin (such as during removal of the pin from a pin receiver).

Each curved leg 340 includes a curved portion 348 including an upper curve 350 and a lower curve 352 opposing the upper curve (or, in other words, curving in an opposite direction from the upper curve). When viewed from the side (wherein one curved leg is substantially hid, or is fully hid, behind the other curved leg) there are a plurality of gaps between the vertical stop and the curved leg. A gap is present between the upper curve and the vertical stop and a gap is present between the lower curve and the vertical stop. In other implementations these gaps need not be present, though configuring the legs to have the gaps present may result in desirable or improved bending or flexing characteristics of the pin.

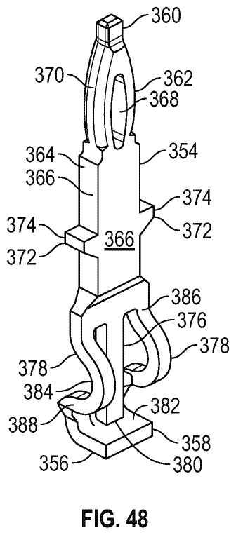

Referring now to FIG. 48, in implementations a flexible press fit pin (pin) 354 includes many elements in common with pin 224 and some different elements. Pin 354 includes a longest length measured from a lower contact surface 356 of a base (horizontal base) 358 to a topmost surface of a tip 360 of an upper contact portion 362. The pin 354 includes a body which in the implementation shown is a rectangular body 364 having a number of side surfaces 366. The upper contact portion 362 includes a deformable portion including a cavity 368 defined by sidewalls and contact surfaces 370 on the outer surfaces of the sidewalls. Functionally, the upper contact portion 362 and deformable portion operate identically to, or similarly to, upper contact portion 232 and deformable portion 236 of pin 224.

Pin 354 also includes one or more stops 372. These operate similarly or identically to stops 262 of pin 224, and they are formed of projections 374, though they have a slightly different shape than stops 262, as can be seen. Instead of being cuboidal in shape, they are trapezoidal, and indeed the stops of any pins disclosed herein may have any closed three-dimensional shape so long as they are configured to function as described above with respect to the stops 262 of pin 224. As illustrated, in some implementations, there are only two stops 372, on opposite sides of the pin 354. While three or four stops could be included in other implementations, having only two stops in the configuration shown in the drawings may provide for easier manufacturing as, in implementations, the entire pin 354 may then be stamped from a single flat sheet of metal and bent/pressed into place (instead of, for instance, beginning with a sheet of metal which has projections in it to begin with or otherwise forming or attaching the additional stops).

The lower portion of pin 354 includes a vertical stop 376 located between two curved legs 378. The vertical stop 376 includes a bottom contact surface 380 facing the upper contact surface 382 of base 358. Thus, in an unflexed configuration, there is a gap 172 between the vertical stop 168 and the base 150. The curved legs 378 flex, when there is a downward pressure applied on the pin, until the vertical stop contacts the base, similar to what has been described with respect to other pins herein. This flexing may be fully elastic or, in implementations, may include plastic deformation.

When viewed from the side (wherein one curved leg is substantially hid, or is fully hid, behind the other curved leg), the curvature 384 of each curved leg 378 includes an upper curve 386 and a lower curve 388. The lower curve is curved opposite the curvature of the upper curve. A gap is present between the vertical stop 376 and the upper curve 386, and a gap is present between the vertical stop 376 and the lower curve 388. When viewed from the back (or from the front), a slanting portion is included at the bottom of each curved leg 378. Each slanting portion couples one of the curved legs with the base 358. Each slanting portion slants downwards and inwards towards the vertical stop along a direction that is diagonal to a plane of curvature of one of the at least two curved legs 378 (the plane of curvature is a plane in which a majority of the curvature of the curved leg may reside, and is parallel with a longest length of the pin). In other implementations the curved leg could exclude the gaps between the curved legs and the vertical stop and/or could exclude the slanting portions, but in various implementations these characteristics may help to achieve desired flexing characteristics of pin 354.

The vertical stop 376, as with other vertical stops, generally does not carry electrical current between the upper contact portion and the base, because during operation it is generally not in contact with the base 358. In general, for all pin implementations disclosed herein, once the pin has been inserted/installed into a pin receiver, the pin will flex back toward an original position to a greater or lesser extent. In other words, there will be some elastic deformation of the pin that will reverse, upon removal of the installation pressure, so that even if the vertical stop (or the first bend of the N-shape) physically contacts the base during installation, after relaxation, the stops will then no longer contact the base, and so will not electrically couple the upper contact portion of the pin with the base. Thus, the vertical stops act as mechanical movement restraining elements. The N-shape of pin 304 is somewhat different in that the first bend 324 always carries current between the upper contact portion 326 and the base 308 when current is flowing through the pin 304, but not through the first bend 324 directly contacting the base instead the current is carried between the first bend and the base through the slanted section 318, second bend 328, second section 330, and third bend 332.

The pin implementations disclosed herein may be made of any conductive materials. In general they will be formed of electrically conductive metals, such as steel, copper, nickel, and so forth, and may include conductive and/or protective coatings (such as corrosion-resistant coatings). In implementations each pin is formed from a single contiguous piece of metal and is formed through any fabrication technique including forging, stamping, punching, molding, casting, and so forth.

For the pin implementations disclosed previously in FIGS. 42-45 and 48, the upper contact portions are configured to mechanically and electrically couple with a pin receiver. The base of each pin is configured to be liquid bonded to a substrate to mechanically and electrically couple the pin to a substrate using any of the methods and sublayer configurations disclosed herein. For those pins with vertical stops, one or more leg(s) of the pin are configured to flex to allow the bottom contact surface of the vertical stop to move toward the upper contact surface of the base in response to a pressure applied to the pin along a direction collinear with a longest length of the pin toward the upper contact surface of the base. In implementations, as shown in the drawings, the base is a horizontal base. The vertical stop in these implementations is configured to stop movement of the pin when the bottom contact surface of the vertical stop contacts the upper contact surface of the base.

Additionally, with the various pin implementations disclosed herein, the deformable portion is configured to deform along a direction perpendicular with the longest length of the pin in response to inserting the upper contact portion into the pin receiver. As described to some extent with respect to the stops 262 and 332, they are configured to prevent the pin(s) from moving relative to the casing of the semiconductor package (once the stops contact the casing) when the pin is removed from the pin receiver. In various implementations, the stops 262, 332 extend substantially perpendicular to, or perpendicular to, the longest length of the pin.

The lower portions of pins 224 and 334 are seen to have an s-shape or a shape somewhat resembling an s-shape. As can also be seen, the curved legs of pins 224 and 334 are parallel with one another, as are the respective s-shapes.

For each pin described herein, the lower portion may compress when a compressive force is applied to the pin along a direction collinear with a longest length of the pin (such as while pressing the pin into a pin receiver), and the lower portion may expand when a tensile force is applied to the pin along a direction collinear with a longest length of the pin (such as while removing the pin from a pin receiver).

In places where the description above refers to particular implementations of electrical interconnects and implementing components, sub-components, methods and sub-methods, it should be readily apparent that a number of modifications may be made without departing from the spirit thereof and that these implementations, implementing components, sub-components, methods and sub-methods may be applied to other electrical interconnects.

What is claimed is:

1. A semiconductor package comprising:
a pin coupled to a substrate;
wherein the pin comprises a titanium sublayer, a nickel sublayer, and one of a silver and tin intermetallic layer or a copper and tin intermetallic layer, the one of the silver and tin intermetallic layer or the copper and tin intermetallic layer having a melting temperature greater than 260 degrees Celsius;
wherein the one of the silver and tin intermetallic layer or the copper and tin intermetallic layer is formed by reflowing a tin layer and one of a silver layer or copper layer with a silver layer of the substrate; and
wherein the substrate is directly coupled to the one of the silver and tin intermetallic layer or the copper and tin intermetallic layer, the substrate comprising a copper layer that was directly coupled with the silver layer before the one of the silver and tin intermetallic layer or the copper and tin intermetallic layer was reflowed.

2. The package of claim 1, wherein an intervening layer was coupled between the nickel sublayer and a copper layer in the copper and tin intermetallic layer before the copper and tin intermetallic layer was reflowed.

3. The package of claim 1, wherein the nickel sublayer is between the titanium sublayer and one of the silver and tin intermetallic layer or the copper and tin intermetallic layer.

4. The package of claim 1, wherein the passivation layer of a die coupled to the substrate comprises one of an oxide, nitride, or polyimide.

5. The pin of claim 1, further comprising:
an upper contact portion comprising a contact surface configured to mechanically and electrically couple with a pin receiver;
a lower portion comprising a single vertical stop and at least two curved legs;
a horizontal base coupled directly to the at least two curved legs; and
a gap between a bottom contact surface of the single vertical stop and an upper contact surface of the horizontal base;
wherein the single vertical stop is located between the at least two curved legs.

6. The pin of claim 1, further comprising:
an upper contact portion comprising a contact surface configured to mechanically and electrically couple with a pin receiver;
a lower portion bent into a single N-shape comprising a first section and a second section;
a horizontal base coupled directly to the second section of the lower portion and having an upper contact surface and the horizontal base extending substantially perpendicularly beyond a width of the upper contact portion; and
a gap between a lower contact surface of the first section and the horizontal base.

7. The pin of claim 1, further comprising:
an upper contact portion comprising a contact surface configured to mechanically and electrically couple with a pin receiver;
a lower portion comprising a single vertical stop and at least two curved legs, wherein the at least two curved legs comprise a first portion and a second portion;
a horizontal base coupled directly to the second portion of the at least two curved legs and having an upper contact surface and the horizontal base extending substantially perpendicularly beyond a width of the upper contact portion; and
a gap between a bottom contact surface of the single vertical stop and the upper contact surface of the horizontal base;
wherein the single vertical stop is located between the at least two curved legs.

8. The pin of claim 1, further comprising:
an upper portion;
a lower portion comprising a single vertical stop, the lower portion further comprising at least two curved portions, each curved portion comprising one of an s-shape or a c-shape;
a horizontal base coupled directly to the at least two curved portions; and
a gap between the single vertical stop and an upper contact surface of the horizontal base;
wherein each of the at least two curved portions further comprise a tapered portion coupled directly with the horizontal base.

9. A semiconductor package comprising:
a pin comprising a metal layer on an end of the pin; and
a substrate comprising an opening therein, the opening comprising a metal layer;
wherein the metal layer of the end of the pin is configured to reflow with the metal layer comprised in the opening in the substrate after the end of the pin is inserted into the opening.

10. The package of claim 9, wherein the metal layer on the end of the pin comprises a titanium sublayer, a nickel sublayer, and one of a silver and tin intermetallic layer or a copper and tin intermetallic layer, the one of the silver and tin intermetallic layer or the copper and tin intermetallic layer having a melting temperature greater than 260 degrees Celsius; and
wherein the one of the silver and tin intermetallic layer or the copper and tin intermetallic layer is formed by reflowing a tin layer and one of a silver layer or copper layer with a silver layer comprised in the metal layer of the substrate.

11. The package of claim 10, wherein the substrate is directly coupled to the one of the silver and tin intermetallic layer or the copper and tin intermetallic layer, the substrate comprising a copper layer that was directly coupled with the silver layer before the one of the silver and tin intermetallic layer or the copper and tin intermetallic layer was reflowed.

12. The package of claim 10, wherein an intervening layer was coupled between the nickel sublayer and a copper layer in the copper and tin intermetallic layer before the copper and tin intermetallic layer was reflowed.

13. The package of claim 10, wherein the nickel sublayer is between the titanium sublayer and one of the silver and tin intermetallic layer or the copper and tin intermetallic layer.

14. The package of claim 9, wherein the end of the pin is a rod with a substantially perpendicular edge.

15. The package of claim 9, wherein the end of the pin is a rod with one of a beveled edge, a chamfered edge, or an angled edge.

16. A semiconductor package comprising:
a pin comprising a base, the base comprising one or more projections extending therefrom and a metal layer on the base; and
a substrate comprising an opening therein comprising one or more recesses configured to receive the one or more projections of the pin, the opening comprising a metal layer;
wherein the metal layer of the base is configured to reflow with the metal layer comprised in the opening in the substrate after the one or more projections of the pin are inserted into the one or more recesses of the opening.

17. The package of claim 16, wherein the one or more projections are one of a right triangular pyramid, a rectangular solid, a pyramid, a conical frustum, or a cone.

18. The package of claim 16, wherein the one or more projections are distributed along a largest planar surface of the base.

19. The package of claim 16, wherein the one or more projections are located at edges of a largest planar surface of the base.

20. The package of claim 16 wherein the base comprises a curved surface from which the one or more projections extend therefrom.
